(19) United States
(12) Patent Application Publication
(10) Pub. No.: US 2007/0057335 A1
(43) Pub. Date: Mar. 15, 2007

(54) Semiconductor device

(76) Inventors: Yoshinori Tsuchiya, Yokohama-shi (JP); Masahiko Yoshiki, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/377,438

(22) Filed: Mar. 17, 2006

(30) Foreign Application Priority Data
Sep. 13, 2005 (JP) 2005-264916

(51) Int. Cl. H01L 29/94

(52) U.S. Cl. 257/412

(57) ABSTRACT

It is made possible to control the effective work function of the gate electrode so that the transistor can have an optimum operating threshold voltage. A semiconductor device includes: a semiconductor substrate; a gate insulating film provided on the semiconductor substrate; a gate electrode provided on the gate insulating film; source/drain regions provided in the semiconductor substrate on both sides of the gate electrode; and a layer which is provided at an interface between the gate electrode and the gate insulating film, and contains an element having an electronegativity different from those of elements constituting the gate electrode and the gate insulating film.

### CROSS-REFERENCE TO RELATED APPLICATION

This application is based upon and claims the benefit of priority from prior Japanese Patent Application No. 2005-264916 filed on Sep. 13, 2005 in Japan, the entire contents of which are incorporated herein by reference.

### BACKGROUND OF THE INVENTION

1. Field of the Invention

The present invention relates to a semiconductor device.

2. Related Art

Silicon very large scaled integrated circuit is one of the fundamental technologies that will support a future advanced information society. Enhancement of performance of a large-scale integrated circuit requires enhancement of performance of MOS devices constituting the LSI circuit. Enhancement of performance of such devices has been basically achieved according to a scaling law. However, in recent years, various physical limitations make it difficult to enhance the performance of devices based on miniaturization and to operate devices themselves. As one of the causes that have brought about such a situation, inhibition of reduction in thickness of an electric insulating film due to the formation of a depletion layer in a polycrystalline silicon gate electrode can be mentioned. As described above, enhancement of performance of MIS devices has been achieved by reducing the thickness of a gate insulating film according to a scaling law, but the formation of a depletion layer in a polycrystalline silicon gate electrode and the existence of inversion-layer capacitance make it difficult to further reduce the thickness of a gate insulating film. In the generation of technology where the thickness of a gate oxide film is less than 1 nm, the depletion-layer capacitance of a polycrystalline silicon gate electrode reaches about 30% of the gate oxide film capacitance. It is known that the depletion-layer capacitance can be decreased by replacing the polycrystalline silicon gate electrode with a metal gate electrode. Also from the viewpoint of reduction in sheet resistance of a gate electrode, it is desired that a metal gate electrode be used as a gate electrode.

However, a CMIS device requires gate electrodes different in work function to allow transistors of different conductivity types to have their respective appropriate threshold voltages. Therefore, when a metal gate is simply used, it is necessary to use two kinds of metal materials, which inevitably complicates the manufacturing process of a CMIS device and increases manufacturing costs. As a technique for simplifying the manufacturing process of a metal gate, injection of an impurity into silicide has been proposed (see, for example, J. Kedzierski et al., IEDM Tech. Dig. (2002) p. 315). However, impurity injection cannot achieve a wide range of control of the work function of a gate electrode. Particularly, it is desired that a metal gate electrode be used for a high-performance transistor device having a low threshold voltage, but impurity insertion cannot achieve work function required for such a high-performance transistor device. Further, there are known various methods for controlling the operating threshold voltage of a transistor by inserting fixed charges into a gate insulating film. However, in a case where the operating threshold voltage of a transistor is controlled by such a method, the carrier mobility in a channel is decreased, thereby significantly inhibiting the enhancement of performance of the transistor achieved by using a metal gate electrode.

### SUMMARY OF THE INVENTION

In view of the circumstances described above, it is an object of the present invention to provide a semiconductor device capable of controlling the effective work function of a gate electrode so that a transistor can have an optimum operating threshold voltage.

A semiconductor device according to a first aspect of the present invention includes: a semiconductor substrate; a gate insulating film provided on the semiconductor substrate; a gate electrode provided on the gate insulating film; source/drain regions provided in the semiconductor substrate on both sides of the gate electrode; and a layer which is provided at an interface between the gate electrode and the gate insulating film, and contains an element having an electronegativity different from those of elements constituting the gate electrode and the gate insulating film.

A semiconductor device according to a second aspect of the present invention includes: a semiconductor substrate; a gate insulating film provided on the semiconductor substrate; a gate electrode provided on the gate insulating film; source/drain regions provided in the semiconductor substrate on both sides of the gate electrode; and a layer which is provided as at least a first atomic layer on the gate electrode side of an interface between the gate electrode and the gate insulating film, and includes an element having an electronegativity different from those of elements constituting the gate electrode and the gate insulating film.

A semiconductor device according to a third aspect of the present invention includes: a semiconductor substrate; a gate insulating film provided on the semiconductor substrate; a gate electrode provided on the gate insulating film; source/drain regions provided in the semiconductor substrate on both sides of the gate electrode; and a layer which is provided as a second or deeper atomic layer on the gate insulating film side of an interface between the gate electrode and the gate insulating film, and includes an element having an electronegativity different from those of elements constituting the gate electrode and the gate insulating film, the element being bonded to an element which the gate electrode include through an oxygen atom.

A semiconductor device according to a fourth aspect of the present invention includes: a semiconductor substrate; a gate insulating film provided on the semiconductor substrate; a gate electrode provided on the gate insulating film; source/drain regions provided in the semiconductor substrate on both sides of the gate electrode; a first layer which is provided as at least a first atomic layer on the gate electrode side of an interface between the gate electrode and the gate insulating film, and includes a first element having an electronegativity different from those of elements constituting the gate electrode and the gate insulating film; and a second layer which is provided as a second or deeper atomic layer on the gate insulating film side of an interface between the gate electrode and the gate insulating film, and includes a second element having an electronegativity different from those of elements constituting the gate electrode and the gate insulating film, the second element being bonded to an element which the gate electrode include through an oxygen atom.

A semiconductor device according to a fifth aspect of the present invention includes: a convex semiconductor layer provided on an insulating layer formed on a substrate; a gate electrode provided to cross and straddle the semiconductor layer; a gate insulating film provided at the intersection region between the semiconductor layer and the gate electrode; source/drain regions provided in the semiconductor layer on both sides of the gate electrode; and a layer provided at an interface between the gate electrode and the gate insulating film and containing an element having an electronegativity different from those of elements constituting the gate electrode and the gate insulating film.

### BRIEF DESCRIPTION OF THE DRAWINGS

FIG. 1 is a cross-sectional view of a semiconductor device according to a first embodiment of the present invention;

FIG. 2 is a graph which shows the result of XPS analysis for determining the bonding state of phosphorus (P) of a one atomic layer inserted into an interface between a gate electrode and a gate insulating film of the semiconductor device according to the first embodiment;

FIG. 3 shows an interface electric dipole modulated by addition of phosphorus to the first atomic layer provided on the electrode side of an interface between NiSix and SiO₂ in a case where NiSi is used as a gate electrode;

FIG. 4 is a graph which shows the C—V characteristics of a MOS capacitor in which P has been inserted into the first atomic layer provided on the electrode side of an interface between a Ni silicide electrode and SiO₂ to form a P—O—Si bond and the C—V characteristics of a MOS capacitor to which no phosphorus has been added;

FIG. 5 is a graph which shows the relation between the amount of modulation of effective work function (φ_{eff} and the areal density of an additive element when a nonmetallic element is added as an additive element to the gate electrode side of an interface between a gate electrode and a gate insulating film;

FIG. 6 is a cross-sectional view of a semiconductor device according to a second embodiment of the present invention;

FIG. 7 is a graph which shows the result of XPS analysis for determining the bonding state of boron (B) inserted into an interface between a gate electrode and a gate insulating film of the semiconductor device according to the second embodiment;

FIG. 8 shows an interface electric dipole modulated by boron that is added to the second atomic layer provided on the insulating film side of an interface between NiSix and SiO₂ so as to be bonded to oxygen in a case where NiSi is used as a gate electrode;

FIG. 9 is a cross-sectional view of a semiconductor device according to a first modification of the second embodiment;

FIG. 10 is a cross-sectional view of a semiconductor device according to a second modification of the second embodiment;

FIG. 11 is a cross-sectional view of a semiconductor device according to a third embodiment of the present invention;

FIG. 12 is a graph which shows the relation between the amount of modulation of effective work function φ_{eff} and the areal density of an additive element when a metal element is added as an additive element to the gate electrode side of an interface between a gate electrode and a gate insulating film;

FIG. 13 is a cross-sectional view of a semiconductor device according to a fourth embodiment of the present invention;

FIG. 14 is a cross-sectional view of a semiconductor device according to a first modification of the fourth embodiment;

FIG. 15 is a cross-sectional view of a semiconductor device according to a second modification of the fourth embodiment;

FIG. 16 is a cross-sectional view of a semiconductor device according to a fifth embodiment of the present invention;

FIG. 17 is a cross-sectional view of a semiconductor device according to a sixth embodiment of the present invention;

FIG. 18 is a cross-sectional view of a semiconductor device according to a seventh embodiment of the present invention;

FIG. 19 is a cross-sectional view of a semiconductor device according to a modification of the fourth embodiment;

FIG. 20 is a cross-sectional view of a semiconductor device according to an eighth embodiment of the present invention;

FIG. 21 is a cross-sectional view of a semiconductor device according to a ninth embodiment of the present invention;

FIG. 22 is a cross-sectional view of a semiconductor device according to a modification of the ninth embodiment;

FIG. 23 is a cross-sectional view of a semiconductor device according to a tenth embodiment of the present invention;

FIG. 24 is a cross-sectional view of a semiconductor device according to an eleventh embodiment of the present invention;

FIG. 25 is a cross-sectional view of a semiconductor device according to a twelfth embodiment of the present invention;

FIG. 26 is a cross-sectional view of a semiconductor device according to a thirteenth embodiment of the present invention;

FIG. 27 is a cross-sectional view of a semiconductor device according to a fourteenth embodiment of the present invention;

FIG. 28 is a cross-sectional view of a semiconductor device according to a fifteenth embodiment of the present invention;

FIG. 29 is a cross-sectional view of a semiconductor device according to a sixteenth embodiment of the present invention;

FIGS. 30A to 30D are cross-sectional views for illustrating the manufacturing steps of a semiconductor device manufacturing method according to a seventeenth embodiment of the present invention;

FIGS. 31A to 31C are cross-sectional views for illustrating the manufacturing steps of a semiconductor device manufacturing method according to a eighteenth embodiment of the present invention;

FIGS. 32A to 32D are cross-sectional views for illustrating the manufacturing steps of a semiconductor device manufacturing method according to a nineteenth embodiment of the present invention;

FIG. 33 is a perspective view of a semiconductor device according to a twentieth embodiment of the present invention;

FIG. 34 is a graph which shows the C—V characteristics of a MOS capacitor according to the first embodiment to which two kinds of elements have been added;

FIG. 35 is a graph which shows the experimental result of determining the dependence of the amount of modulation of effective work function on the amount of an impurity present at an interface between a gate electrode and a gate insulating film in a case where BF₂ or B is added as an impurity;

FIG. 36 is a graph which shows the effect of B added to an interface between Ni silicide and SiO(N) in a case where the surface of a gate insulating film made of SiO₂ is nitrided by exposing in an atmosphere of nitrogen plasma;

FIG. 37 is a graph which shows boron concentration distribution in a depth direction in the case of FIG. 36; and

FIG. 38 is a graph for explaining a method for determining an interface between Ni silicide and SiO₂ in SIMS analysis.

### DETAILED DESCRIPTION OF THE INVENTION

Hereinbelow, embodiments of the present invention will be described with reference to the accompanying drawings.

### First Embodiment

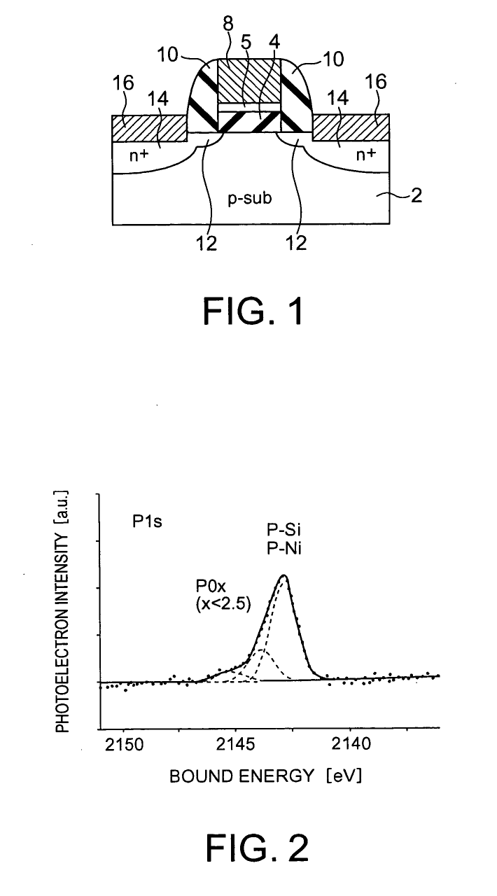

FIG. 1 shows a semiconductor device according to a first embodiment of the present invention. The semiconductor device according to the first embodiment is an n-type MOS transistor. In this semiconductor device, a gate insulating film 4 formed from a thermally-oxidized silicon film is provided on a p-type silicon substrate 2. The film thickness of the gate insulating film 4 is preferably 2 nm or less. On the gate insulating film 4, a gate electrode 8 is provided. The gate electrode 8 is made of Ni silicide that is a compound of nickel (Ni) and silicon (Si). On the gate electrode side of an interface between the gate electrode 8 and the gate insulating film 4, a one atomic layer 5 containing phosphorus (P) of at a density of one atomic layer or less is provided. The areal density of phosphorus in the one atomic layer 5 is 1×10¹³ cm⁻² or more but 1×10¹⁵ cm⁻² or less. On the side faces of the gate electrode 8, a gate side wall 10 made of an insulating material is provided.

In the p-type silicon substrate 2, extension layers 12 and source/drain regions 14 are provided as n-type high-concentration impurity regions on both sides of the gate electrode 8. On each of the source/drain regions 14, a contact electrode 16 made of Ni silicide is provided.

FIG. 2 shows the result of photoelectron spectroscopy (hereinafter, also referred to as “XPS” (X-ray Photoelectron Spectroscopy)) analysis for determining the bonding state of phosphorus (P) of the one atomic layer 5 inserted into an interface between the gate electrode 8 and the gate insulating film 4 of the semiconductor device according to the first embodiment. The spectrum shown in FIG. 2 represents the bonding state of phosphorus (P). In this analysis, hard X-ray photoelectron spectroscopy using high-intensity hard X-ray as a source of excited X-ray was employed to increase detection depth and sensitivity as compared to those of normal XPS analysis. The 1s spectrum of phosphorus (P) is the superposition of spectra of phosphorus (P) in various bonding states. The peak corresponding to the smallest bound energy is derived from phosphorus (P) forming a metallic bond, that is, phosphorus (P) existing in Ni silicide as a result of diffusing in the gate electrode by heat treatment carried out after the formation of the gate electrode.

On the other hand, two peaks appeared on the high energy side indicate the existence of phosphorus (P) bonded to oxygen. More specifically, phosphorus (P) existing at the interface forms a very stable bond, that is, a P—O bond. However, the energy values of the XPS spectrum also indicate that not all but part of the bonds of each phosphorus is bonded to oxygen. From the result of XPS analysis, phosphorus existing at the interface absolutely exists on the gate electrode 8 side of the interface, and is bonded to oxygen atoms of the gate insulating film 4 at the interface. In this case, the P—O bond forms a large electric dipole at the interface because of a difference in electronegativity between the elements P and O.

In general, the work function of the surface or interface of material is greatly influenced by not only the energy position of the Fermi level in the substance but also the conditions of the surface or interface of the material. Therefore, as described above, addition of an element having a different electronegativity to the interface modulates an interface electric dipole, thereby greatly changing an effective work function φ_{eff} that is a work function at an interface between the gate electrode and SiO₂ as compared to that before addition of such an element.

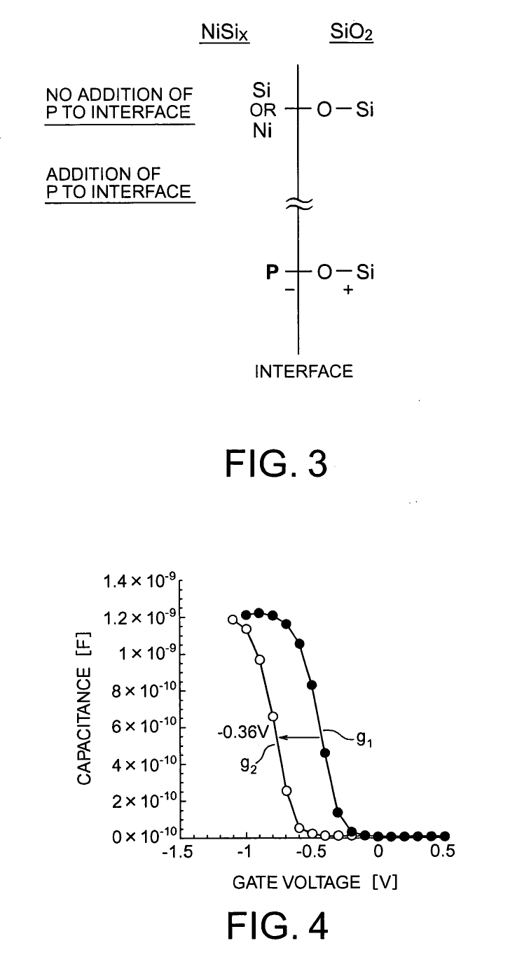

FIG. 3 shows an interface electric dipole modulated by addition of phosphorus in a case where NiSi is used as a gate electrode as in the case of the first embodiment. As shown in FIG. 3, phosphorus (P) existing at an interface between NiSi and SiO₂ is bonded to oxygen to form a P—O—Si bond. The electronegativity of phosphorus (P) is larger than those of silicon (Si) and nickel (Ni) constituting the electrode. Therefore, at the interface in the semiconductor device according to the first embodiment, polarization of electric charge distribution toward the insulating film side becomes smaller as compared to a case where phosphorus (P) is not inserted into the interface, so that the interface electric dipole is modulated. (Here, Pauling's electronegativity values described in Web Elements (http://www.webelements.com/index.html) are used.) As a result, the effective work function Φ_{eff} in the semiconductor device according to the first embodiment becomes smaller as compared to a case where phosphorus (P) is not added. Namely, in a case where a gate electrode interface of a MOS device has such a structure described above, the flat band voltage Vfb and the operating threshold voltage of the MOS device are greatly modulated toward the negative side.

FIG. 4 shows the C—V characteristics of a MOS capacitor in which phosphorus (P) has been inserted into the first atomic layer provided on the electrode side of an interface between a Ni silicide electrode and SiO₂ to form a P—O—Si bond and the C—V characteristics of a MOS capacitor to which no phosphorus has been added. In FIG. 4, the graph g₁ shows the C—V characteristics of the MOS capacitor to which no phosphorus (P) has been added, and the graph g₂ shows the C—V characteristics of the MOS capacitor to which phosphorus (P) has been added. The amount of phosphorus (P) added to the MOS capacitor is 1.1×10¹⁴ cm⁻² in terms of areal density.

As shown in FIG. 4, as a result of inserting phosphorus (P) into the interface, the flat band voltage Vfb was greatly changed to about −0.36 V.

On the other hand, in the case of conventional art (see, for example, J. Kedzierski et al., IEDM tech. Dig. (2002) p. 315), the effective work function Φ_{eff} of an interface between a gate electrode and an insulating film is controlled by inserting a silicon layer, having a thickness of 5 Å or less and doped with a high concentration of impurity, into the interface. In this case, the maximum modulation width at the time when phosphorus (P) is used as an impurity is 0.2 eV.

Therefore, the modulation width achieved by the first embodiment is larger than the control range achieved by the conventional art. In addition, in the case of the MOS capacitor represented by the graph g₂ in FIG. 4, the areal density of phosphorus (P) of the first atomic layer is achieved by adding phosphorus (P) in a trace amount corresponding to the level that one of ten atoms is replaced with phosphorus (P).

Since the modulation width is determined by the areal density of an interface electric dipole, it is possible to double the modulation width by simply doubling the areal density of a phosphorus (P) atom of the one atomic layer 5. That is, in a case where phosphorus (P) is used as an impurity, it is possible to achieve a modulation width of effective work function Φ_{eff} of about 0.5 to 1.0 eV by inserting phosphorus (P) into the interface so that the atomic percentage of phosphorus of the one atomic layer 5 becomes 10 to 20%. Such a modulation width is on the same level as the control range of the effective work function Φ_{eff} required for future LSIs.

As described above, according to the first embodiment, by providing the one atomic layer 5 containing phosphorus (P) at an interface between the gate electrode 8 and the gate insulating film 4, it is possible to obtain a metal gate structure which can be applied to MISFET devices having different operating threshold voltages in spite of the fact that only one metal material is used for gate electrodes of the MISFET devices.

An element to be added to the interface is not limited to phosphorus (P). By adding any of the elements mentioned below instead of phosphorus, it is possible to further increase the modulation width, which makes it easier to control the effective work function Φ_{eff}. One of the requirements for this is to use an element having a larger electronegativity than that of phosphorus (P).

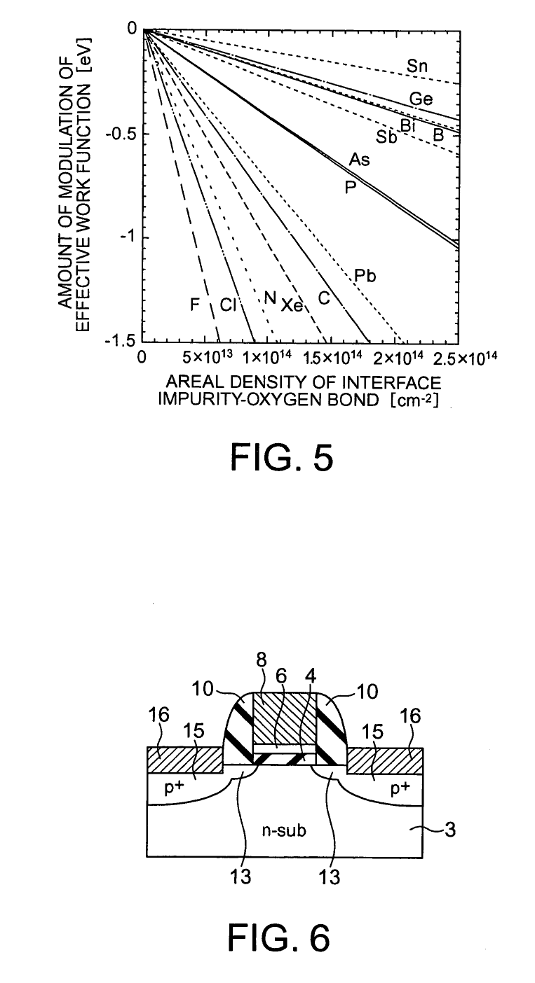

FIG. 5 is a graph which shows the modulation effect obtained by adding an additive element in a case where NiSi is used as a gate electrode. As can be seen from FIG. 5, by using a nonmetallic element having a larger electronegativity than that of phosphorus (P), such as nitrogen (N), carbon (C), fluorine (F) or chlorine (Cl), it is possible to increase the amount of change of the effective work function even when the interface density of such an additive element is lower than that of phosphorus. For example, in a case of carbon (C) is used as an additive element, even when the amount of carbon added to the interface is about half that of phosphorus (P), it is possible to achieve the same level of effective work function Φ_{eff} modulation that is achieved by adding phosphorus (P). Further, in a case where fluorine (F), nitrogen (N) or chlorine (Cl) is used as an additive element, even when the amount of such an element added to the interface is about a quarter of that of phosphorus (P), it is possible to achieve the same level of effective work function Φ_{eff} modulation that is achieved by adding phosphorus (P). That is, even when the amount of an element such as F, N or Cl added to the interface is very small, e.g., 1×10¹⁴ cm⁻² or less, it is possible to easily achieve a large amount of effective work function Φ_{eff} modulation of about 1 eV.

Further, even in a case where a nonmetallic element having a smaller electronegativity than that of phosphorus (P) is used as an additive element, it is possible to increase the modulation width of the effective work function Φ_{eff} as long as the nonmetallic element has a relatively large atomic radius (e.g., arsenic (As) or antimony (Sb)). The reason for this is as follows. An element having a relatively large atomic radius cannot easily diffuse in the gate insulating film so that a larger amount of the element is localized in the first atomic layer adjacent to the interface. Therefore, it is possible to easily add a high concentration of the element to the first atomic layer provided on the gate electrode side of the interface, thereby easily increasing the density of the element at the interface.

Each of the embodiments of the present invention utilizes a difference in electronegativity between an additive element and an element constituting a gate electrode. Therefore, in a case where an element constituting a gate electrode is different from an element constituting the NiSi electrode used in the first embodiment, the quantitative relation between the amount of modulation and the amount of an impurity added to the interface is not necessarily the same as that shown in FIG. 5. Specifically, in a case where the metal gate electrode is made of an element having a larger electronegativity, a difference in electronegativity between the element constituting the metal gate electrode and each of the additive elements shown in FIG. 5 becomes smaller, and therefore modulation effect is smaller than that shown in FIG. 5. On the other hand, in a case where the metal gate electrode is made of an element having a smaller electronegativity, modulation effect is larger than that shown in FIG. 5. Further, even in a case an element other than the elements shown in FIG. 5 which has a smaller electronegativity than those of the elements shown in FIG. 5 is used as an additive element, it is possible to obtain modulation effect as long as the additive element has a larger electronegativity than that of an element constituting the electrode. Also in the following embodiments, the effect of modulating the effective work function Φ_{eff} will be described by using as an example, a case where NiSi is used as a gate electrode. In all the embodiments, the effective work function Φ_{eff} is modulated as long as there is a difference in electronegativity between an additive element and an element constituting a gate electrode or a gate insulating film. The direction and amount of modulation are determined by the magnitude relation of electronegativity between the additive element and the element constituting a gate electrode or a gate insulating film and the absolute value of a difference between these electronegativity values, respectively. Therefore, the first embodiment can also be applied to a case where a gate electrode is made of any element other than NiSi. In such a case, an additive element should be appropriately selected so that a difference in electronegativity between an additive element and an element constituting a gate electrode becomes large. For example, in a case where NiSi is used as a gate electrode as in the case of the first embodiment, since the Pauling's electronegativity values of nickel (Ni) and silicon (Si) are both 1.9, the use of an additive element having a Pauling's electronegativity larger than 1.9 makes it possible to obtain modulation effect as shown in FIG. 5. It is to be noted that also in the following embodiments, Pauling's electronegativity values are used.

As described above with reference to the conventional art, in a case where a high-concentration silicon layer is inserted into an interface between a gate electrode and an insulating film, there is a negative effect that an obtained MIS transistor has a parasitic capacitance of about 1 to 3 Å in terms of a silicon oxide film thickness. Such a negative effect inhibits the enhancement of performance of the MIS transistor even when a metal electrode is used (IEEE Trans. Electron Devices, 52 (2005) 39).

On the other hand, according to the first embodiment, the gate electrode and its interface with the insulating film are all made of a metal (silicide), and therefore it is possible to completely eliminate the negative effect associated with the conventional art. Further, the metal electrode may contain an element (in the first embodiment, a phosphorus (P) atom) which forms an electric dipole in the first atomic layer adjacent to the interface, as long as the concentration of the element is low. However, the average atomic density of the element in the entire gate electrode must be about 10 atomic % or less of a metal mainly constituting the gate electrode so that the element does not affect the work function of the metal. Such a trace amount of the impurity element does not affect the vacuum work function of the bulk of the gate electrode, and the charge effect of the impurity element is completely shielded by free electrons in the metal.

Also in the following embodiments, the gate electrode may contain an element added to the interface unless otherwise specified. Particularly, in an area in the vicinity of the interface, there is a case where an impurity element exists at a little less than 10 atomic % because the impurity element in an incomplete bonding state contained in the first atomic layer adjacent to the interface penetrates into the gate electrode by heat treatment.

It should be noted that the amount of an impurity added to the first atomic layer adjacent to the interface can never exceed the areal density of the metal of the gate electrode. If the amount of an impurity added to the first atomic layer adjacent to the interface exceeds the areal density of the metal of the gate electrode, adhesion between the metal electrode and the impurity layer becomes poor. As long as the element shown in FIG. 5, such as nitrogen (N), carbon (C), fluorine (F) or chlorine (Cl) is used as an additive element, it is possible to achieve a modulation amount of 1 eV, even when the amount of such an element added to the interface is one or more orders of magnitude smaller than the areal density of the metal of the gate electrode, that is, it is possible to obtain a sufficient modulation effect required for an LSI without such a problem described above.

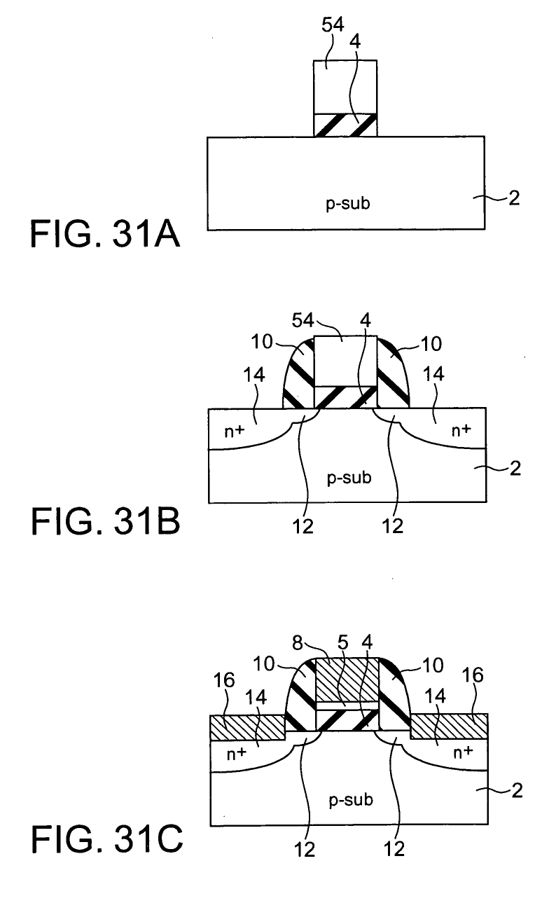

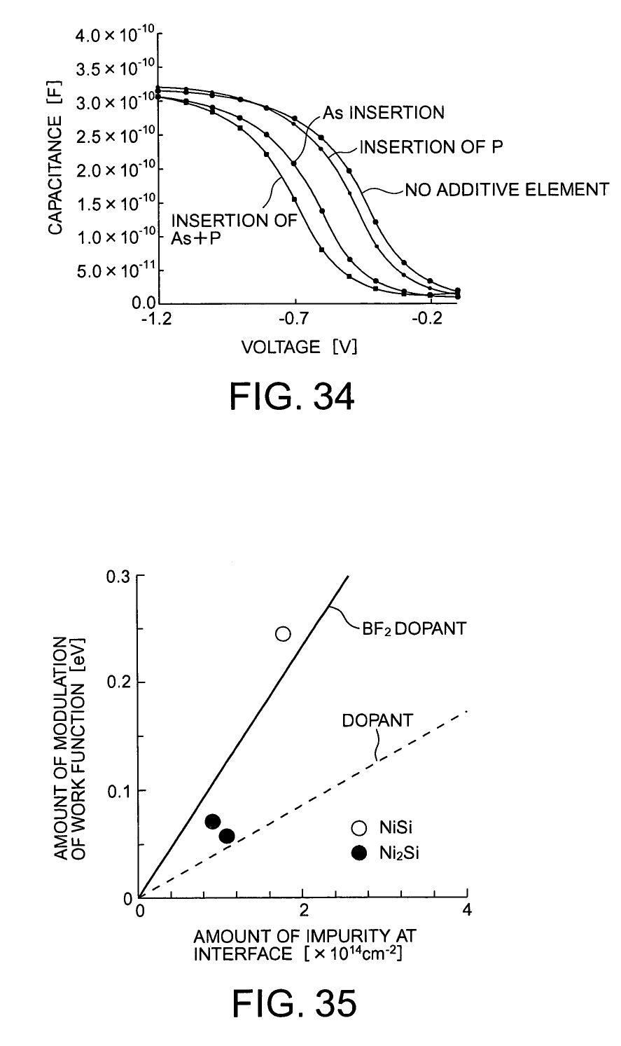

Further, when two or more kinds of additive elements which occupy different sites in the interface are used, the amount of change of work function is the sum of individual effects obtained by adding each of these additive elements. FIG. 34 shows the C—V characteristics of a MOS capacitor to which phosphorus (P) and arsenic (As) have been inserted into the electrode side of an interface between NiSi and SiO₂. As can be seen from FIG. 34, the shift amount of the C—V curve of the MOS capacitor is larger as compared to a case where only As or P is inserted into the interface, that is, the effective work function of the electrode of the MOS capacitor is more largely modulated. In a case where an additive element is introduced by snow-plow effect associated with silicidation or by ion implantation and thermal diffusion carried out after the formation of a gate electrode (which will be described below with reference to FIG. 31), the highest possible areal density of each additive element added to an interface between a gate electrode and an insulating film is limited by the number of sites which can be occupied by the element. Therefore, in a case where only one kind of element is used as an additive element, there is a possibility that the additive element cannot be added to an interface between the gate electrode and the insulating film in an amount necessary to sufficiently modulate the effective work function, depending on the conditions of the interface. In this case, by using two or more kinds of additive elements which occupy different sites in the interface, it is possible to sufficiently modulate the effective work function.

Although Ni silicide is used as the gate electrode in the first embodiment, an optimum material of the electrode can be appropriately selected in view of, for example, the operating threshold voltage of the transistor or a manufacturing process. Particularly, in a case where a noble metal-based material is selected, it is possible to improve adhesion between the electrode and the insulating film (which will be described later). In addition, such a noble metal electrode having an effective work function Φ_{eff} appropriate to a p-type MIS transistor can also be used for the n-type MOS transistor according to the first embodiment, and therefore it is possible to significantly simplify the manufacturing process of an LSI including transistors of both conductivity types on the same substrate, such as a CMIS device.

Further, although a silicon oxide film is used as the gate insulating film in the first embodiment, an insulating material having a higher permittivity than that of a silicon oxide film (that is, a high-k film) may alternatively be used. Examples of such an insulating material include Si₃N₄, Al₂O₃, Ta₂O₅, TiO₂, La₂O₅, CeO₂, ZrO₂, HfO₂, SrTiO₃, and Pr₂O₃. Further, a material obtained by mixing silicon oxide with metal ions can also be effectively used. Examples of such a material include zirconium (Zr) silicate and hafnium (Hf) silicate, and these materials can be used in combination of two or more of them. Furthermore, a gate insulating film obtained by adding nitrogen to a high-k film, such as HfSiON can also be used. By adding nitrogen to a gate insulating film, it becomes easy to manufacture a gate structure in a manufacturing process because the thermal stability of the gate insulating film is improved. The material of a gate insulating film can be appropriately selected so as to meet the requirements of each generation of transistors. Also in the following embodiments, a silicon oxide film is used as the gate insulating film and Ni silicide is used as the gate electrode, but as a matter of course, the silicon oxide film and Ni silicide can be replaced with a high-k film and a metal material, respectively unless otherwise specified.

The use of the structure according to the first embodiment makes it possible to improve adhesion between the gate electrode and the insulating film. In a case where a noble metal or a compound thereof is used as an electrode, the effect of improving adhesion between the gate electrode and the insulating film is significantly large. In general, at an interface between a metal and an insulating film, atoms are bonded together in a discontinuous manner so that adhesion between the metal and the insulating film is poor. Particularly, since a noble metal element is not easily bonded with oxygen, a gate electrode made of a noble metal is easily peeled off from an insulating film at high temperatures. For this reason, a noble metal cannot be used for a gate electrode.

On the other hand, in the first embodiment, phosphorus (P) contained in the metal electrode is bonded to oxygen contained in the insulating film, and therefore adhesion between the metal electrode and the insulating film is improved. From such a viewpoint, it becomes possible to use a noble metal material (e.g., platinum (Pt), iridium (Ir) or palladium (Pd)) as a metal species of the metal electrode, even though adhesion between the element of the noble metal material and the insulating film is poor.

Next, a semiconductor device according to a modification of the first embodiment will be described. The semiconductor device according to a modification of the first embodiment has the same structure as the semiconductor device according to the first embodiment shown in FIG. 1 except that the gate electrode 8 is made of platinum (Pt) instead of Ni suicide. It is to be noted that the gate electrode can also be made of a noble metal other than platinum (Pt) or a noble metal compound having metallic properties, such as PtSi or PtGe.

In general, adhesion between such a metal and an insulating film is unstable because an interface reaction does not occur, and therefore in a case where such a metal is used for a gate electrode, the gate electrode is peeled off from the insulating film. However, in the first embodiment, the one atomic layer 5 containing phosphorus (P) is provided at an interface between the gate electrode 8 and the gate insulating film 4, and therefore adhesion between the gate electrode 8 and the gate insulating film 4 is improved. In addition, it is also possible to achieve a gate electrode having a low effective work function Φ_{eff} required for an n-type MOS transistor, that is, a gate electrode having a Fermi level at an energy position shallower than the center of a silicon forbidden band. In this case, the areal density of phosphorus (P) added to the interface is preferably 1×10¹³ cm⁻² or more but 1×10¹⁵ cm⁻² or less. In a case where an element other than phosphorus (P) is used, as shown in FIG. 5, the amount of the element added to the interface is determined in view of the electronegativity and atomic radius of the element so that the effective work function φ_{eff} of a metal constituting the electrode can be modulated and that the transistor can have an appropriate threshold voltage.

According to the modulation of the first embodiment, it is possible to adjust the effective work function Φ_{eff} of an interface between the gate electrode 8 and the gate insulating film 4 to any value by adding an element to the interface. Therefore, as a metal, a material having thermal stability capable of withstanding heat treatment in a manufacturing process and a low resistivity is used. Examples of such a metal species satisfying these requirements include Ta, Ru, Ti, Hf, Zr, Pt, Nb, W, Mo, V, Cr, Ir, Re, Tc, and Mn. Alternatively, compounds of these metal species may be used to improve thermal stability. The areal density of a substance segregated at the interface is appropriately adjusted according to the work function of the metal.

In the first embodiment and the modification of the first embodiment, Ni silicide is used as a material of the upper contact provided on the source/drain regions, but various germanosilicides and silicides of V, Cr, Mn, Y, Mo, Ru, Rh, Hf, Ta, W, Ir, Co, Ti, Er, Pt, Pd, Zr, Gd, Dy, Ho, and Er which have metallic electrical conducting properties may alternatively be used as materials of the contact. Also in the following embodiments, Ni germanosilicide is used as a material of the gate electrode, but as a matter of course, various germanosilicides can be used instead of Ni germanosilicide unless otherwise specified. A metal material of a gate electrode is selected according to a threshold voltage required for each technology generation of devices.

Further, in the first embodiment and the modification of the first embodiment, since an element for modulating an interface electric dipole is added on the electrode side of the interface, the reliability of the gate insulating film is not impaired and the permittivity of the gate insulating film is not changed.

As has been described above, according to the first embodiment, it is possible to control the effective work function of the gate electrode so that the transistor can have an optimum operating threshold voltage.

### Second Embodiment

FIG. 6 shows a semiconductor device according to a second embodiment of the present invention. The semiconductor device according to the second embodiment is a p-type MOS transistor. In this semiconductor device, a gate insulating film 4 formed from a thermally-oxidized silicon film is provided on an n-type silicon substrate 3. The film thickness of the gate insulating film 4 is preferably 2 nm or less. On the gate insulating film 4, a gate electrode 8 is provided. The gate electrode 8 is made of Ni silicide that is a compound of nickel (Ni) and silicon (Si). On the gate insulating film side of an interface between the gate electrode 8 and the gate insulating film 4, a layer 6 containing boron (B) at a density of one atomic layer or less is provided so that boron is bonded to an element constituting the gate electrode through oxygen. The areal density of the layer 6 is 1×10¹³ cm⁻² or more but 1×10¹⁵ cm⁻² or less. On the side faces of the gate electrode 8, a gate side wall 10 made of an insulating material is provided.

In the n-type silicon substrate 3, extension layers 13 and source/drain regions 15 are provided as p-type high-concentration impurity regions on both sides of the gate electrode 8. On each of the source/drain regions 15, a contact electrode 16 made of nickel (Ni) silicide is provided.

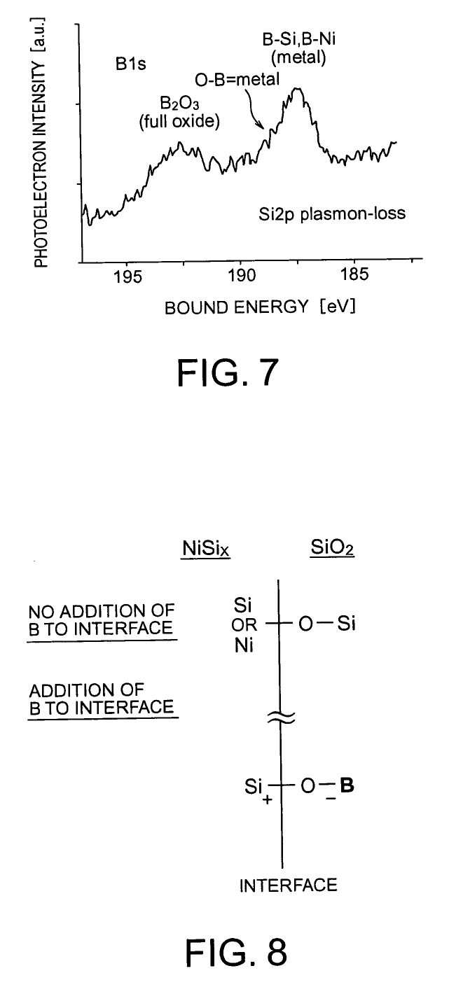

FIG. 7 shows the result of XPS analysis for determining the bonding state of boron (B) of the layer 6 inserted into an interface between the gate electrode 8 and the gate insulating film 4 of the semiconductor device according to the second embodiment. The spectrum shown in FIG. 7 represents the bonding state of boron (B). Prior to the XPS analysis, the silicon substrate 3 was removed by etching to expose the lower interface of the gate insulating film 4. Then, boron (B) segregated at an interface between the gate electrode 8 made of Ni silicide and the gate insulating film 4 formed from a Si oxide film was analyzed through SiO₂.

As can be seen from FIG. 7, the spectrum appeared on the low energy side is derived from metallic boron (B). This is because part of boron added to the interface has penetrated into the gate electrode in trace amounts due to heat treatment carried out after the formation of the gate electrode 8 in the manufacturing process of the semiconductor device according to the second embodiment. On the other hand, the peaks appeared on the high energy side are derived from oxidized boron (B). Further, the bound energy values of these peaks indicate that all of the bonds of boron (B) are bonded to oxygen to form B₂O₃. Specifically, as shown in FIG. 8, boron (B) existing on the gate insulating film side of an interface between the gate electrode and the gate insulating film is bonded to the metal electrode through oxygen at the interface. In contrast to the first embodiment, polarization of electric charge distribution toward the insulating film 4 side becomes larger due to addition of boron (B) so that an interface electric dipole is modulated. As a result, the effective work function Φ_{eff} is modulated to become large. The reason for this is as follows. The boron (B) existing in the second atomic layer from the interface through oxygen is bonded to the oxygen to form a B—O—Si bond (the Si is an element constituting the gate electrode). The electronegativity of boron (B) is larger than that of silicon (Si) constituting the insulating film and bonded to oxygen. Therefore, in the semiconductor device according to the second embodiment, the electron charge distribution at the interface is polarized toward the gate insulating film side as compared to a case where boron (B) is not inserted to the gate insulating film side of the interface, so that an interface electric dipole is modulated. In the second embodiment, by virtue of such an electric dipole modulation effect at an interface between the gate electrode 8 and the gate insulating film 4, the effective work function Φ_{eff} of the interface is larger as compared to a case where boron (B) is not added. That is, in a case where a MOS device has such a structure described above at an interface between a gate electrode and a gate insulating film, the flat band voltage (Vfb) and the operating threshold voltage of the MOS device are largely modulated toward the positive side as compared to a case where boron (B) is not added.

In the second embodiment, boron (B) is used as an impurity because boron can be easily added to the insulating film side of the interface, which will be described later in detail with reference to a method for manufacturing the semiconductor device according to the second embodiment. In order to further increase the amount of modulation of the flat band voltage, that is, the effective work function Φ_{eff} of the gate electrode, a nonmetallic atom which can enhance the effect of an interface electric dipole should be used as in the case of the first embodiment. If the assumption is made that the amount of an element to be added to the interface is the same, the addition of an element having a larger electronegativity and a larger atomic radius can make the amount of modulation of the effective work function larger. In a case where an oxide film is used as the gate insulating film, the relation between an additive element and the amount of modulation is the same as that of the first embodiment shown in FIG. 5, but the direction of modulation is opposite to that of the first embodiment.

FIG. 35 is a graph which shows the experimental result of determining the dependence of the modulation amount of the effective work function on the amount of an impurity added to the interface in a case where BF₂ or B is added as an impurity. The effective work function is determined from an extrapolation point of a flat band voltage at which the thickness of a gate insulating film is 0, which is determined from the C—V characteristics of a MOS capacitor. The amount of the impurity at the interface is an integrated amount of B piled up at the interface in SIMS analysis. As can be seen from FIG. 35, the modulation effect of BF₂ is larger than that of B. This is because, as described with reference to FIG. 5, BF₂ contains fluorine (F) having a relatively large electronegativity. The ratio of the amount of change of effective work function to the amount of the impurity added to the interface determined by experiment is smaller than the ratio of the amount of change of effective work function to the areal density of the bond existing at the interface shown in FIG. 5. This is because all of the atoms of the additive element existing at the interface do not necessarily form the bonds shown in FIGS. 3 and 8, and these bonds are not necessarily perpendicular to the interface.

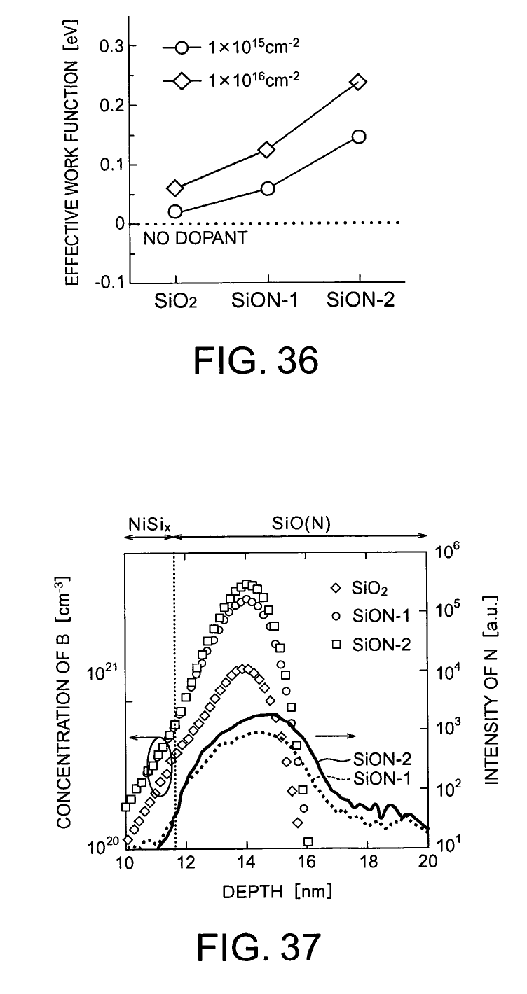

FIG. 36 is a graph which shows the effect obtained by adding B to an interface between Ni silicide and SiO(N) in a case where the surface of the gate insulating film made of SiO₂ is nitrided by exposing in an atmosphere of nitrogen plasma. In this case, boron was added to the interface by utilizing snow-plow effect associated with silicidation that will be described with reference to FIG. 31. The N concentration of SiON-1 on the electrode side is 1 atomic % or more but 10 atomic % or less, and the N concentration of SiON-2 is 10 atomic % or more. As can be seen from FIG. 36, a larger amount of nitrogen of SiON more enhances the effect obtained by adding B. That is, addition of N makes it possible to further enhance the effect obtained by adding B.

FIG. 37 is a graph which shows the concentration distribution of B in a depth direction in the case shown in FIG. 36. As can be seen from FIG. 37, the maximum concentration of B inserted into the gate insulating film side of the interface is increased as the N concentration of the gate insulating film is increased. This is because the insertion of N which can form a very stable bond with B into the gate insulating film side of the interface increases the segregation coefficient of B. In the second embodiment, a depth at which the N concentration and the B concentration are the maximum is about 2 nm from the interface. Therefore, the effect obtained by adding B is smaller than that at the maximum concentration. However, by bringing the depth profile of nitrogen closer to the interface by shortening the time of a plasma nitriding process, it is possible to more effectively increase the effective work function as compared to the case of the second embodiment. The same goes for a case where a high-k film is used as the gate insulating film. It is known that also in a case where a HfSiO film is used, it is possible to control diffusion of B into the Si substrate by adding N to the HfSiO film as in the case of the SiO₂ film. Therefore, it is possible to control the effect obtained by adding B by controlling distribution of N in the gate insulating film.

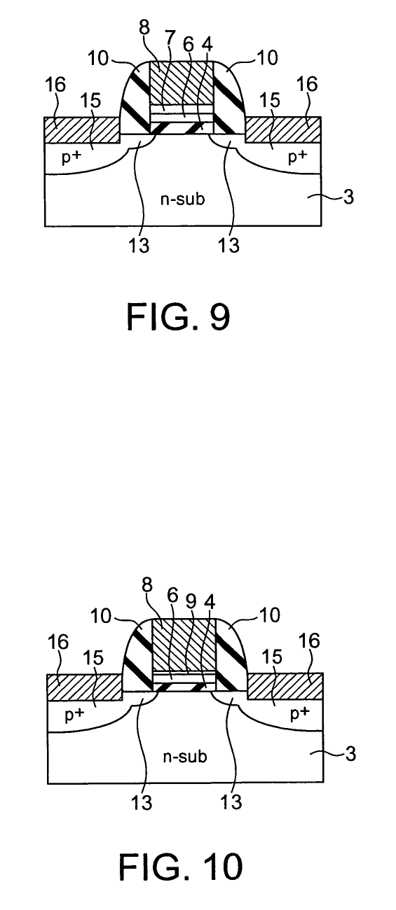

As an additive element, the elements described with reference to the first embodiment are preferably used because they are not easily diffused due to heat treatment. Further, the additive element may be distributed not only in the second atomic layer from an interface between the gate electrode and the gate insulating film through oxygen of the first atomic layer provided on the insulating film side of the interface but also in the insulating film to a certain extent. In this case, each of the electric dipoles obtained by adding boron (B) existing in the third or deeper layers is canceled out, and therefore the effect of modulating the effective work function Φ_{eff} is not impaired. However, boron distributed in an area closer to a channel region serves as a scatterer for carriers in the channel, and interferes with the operation of the device. Therefore, it is usually required that the areal density of the additive element existing at an interface between the insulating film and the silicon substrate 3 be 1×10¹² cm⁻² or less. If the first atomic layer provided on the gate electrode side of the interface also contains the same additive element, electric dipoles opposite in direction to each other are formed so that the effect thereof is canceled out so that the modulation width is decreased, which is not advantageous from the viewpoint of modulation of the effective work function Φ_{eff}. However, as described with reference to the first embodiment, in a case where a metal that is poor in adhesion with the insulating film, such as a noble metal, is used for the electrode, addition of an element to the electrode side of the interface improves adhesion between the electrode and the insulating film. FIG. 9 shows a semiconductor device according to a first modification of the second embodiment. This semiconductor device has a one atomic layer 7 provided on the gate electrode side of an interface between a gate electrode and an insulating film. The one atomic layer 7 contains boron (B) at a areal density that is one order of magnitude smaller than that of an additive element (boron (B)) existing in a layer 6 provided on the insulating film side of the interface. It can be said that such a structure is more advantageous because it is possible to improve adhesion of the interface while keeping the effect of modulating the effective work function Φ_{eff}. As a metal for the gate electrode, transition metals that are excellent in adhesion with the gate insulating film or compounds thereof are preferably used, but as described above, it becomes possible to use a noble metal as a material for the gate electrode by allowing a trace amount of the noble metal to exist on the electrode side of the interface. The areal density of the material segregated at the interface is appropriately adjusted according to the work function of the metal.

In a case where the gate insulating film is a high-k film other than SiO₂, it is necessary to use as an additive element, a nonmetallic material having a larger electronegativity than that of a metal element constituting the gate insulating film. In general, a high-k film is mainly made of an oxide of a transition metal having a smaller electronegativity than that of silicon. Therefore, in a case where a nonmetallic element is added at the same areal density as that of a case where a silicon oxide film is used, the effect of an electric dipole is enhanced so that the modulation width of the effective work function φ_{eff} is increased. However, in a case where the insulating film contains nitrogen, such as HfSiON, the effect of modulating the effective work function is smaller as compared to a case where the insulating film does not contain nitrogen.

FIG. 10 shows a semiconductor device according to a second modification of the second embodiment. The semiconductor device has a layer 6 located immediately above a gate insulating film 4. The layer 6 contains boron (B) as an additive element at a density of one atomic layer or less. On the layer 6, a one atomic layer 9 obtained by adding oxygen at a density of one atomic layer is provided. On the one atomic layer 9, a gate electrode 8 made of a metal is provided. As in the case of the second embodiment, an electric dipole of B—O—Si exists at an interface between the gate electrode and the gate insulating film. According to this modification, it is possible to control the effective work function φ_{eff} without adversely affecting channel mobility because boron (B) is added only to the layer 6. In this case, preferred examples of a material for the electrode include transition metal elements and compounds thereof.

In the second embodiment and the modifications of the second embodiment, nickel (Ni) silicide is used as the gate electrode, but an optimum material for the electrode can be appropriately selected according to the operating threshold voltage of the transistor and a manufacturing process. The effective work function modulation effect obtained by the additive element does not depend on an element constituting the electrode. Particularly, an electrode made of a transition metal or a compound thereof having an effective work function φ_{eff} appropriate to an n-type MIS transistor can also be used for the p-type MOS transistor according to the second embodiment, and therefore it is possible to significantly simplify the manufacturing process of an LSI including transistors of both conductivity types on the same substrate, such as a CMIS device.

As has been described above, according to the second embodiment, it is possible to control the effective work function of the gate electrode so that the transistor can have an optimum operating threshold voltage.

### Third Embodiment

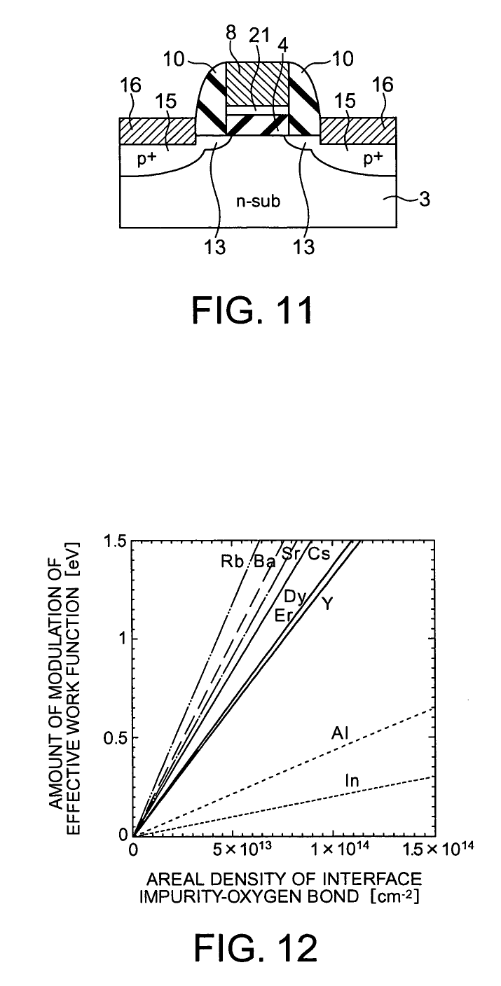

FIG. 11 shows a semiconductor device according to a third embodiment of the present invention. The semiconductor device according to the third embodiment is a p-type MOS transistor. In this semiconductor device, a gate insulating film 4 formed from a thermally-oxidized silicon film is provided on an n-type silicon substrate 3. The film thickness of the gate insulating film 4 is preferably 2 nm or less. On the gate insulating film 4, a gate electrode 8 is provided. The gate electrode 8 is made of Ni suicide that is a compound of nickel (Ni) and silicon (Si). On the gate electrode side of an interface between the gate electrode 8 and the gate insulating film 4, a one atomic layer 21 containing erbium (Er) at a density of one atomic layer or less is provided. The areal density of the one atomic layer 21 is 1×10¹³ cm⁻² or more but 1×10¹⁵ cm⁻² or less. On the side faces of the gate electrode 8, a gate side wall 10 made of an insulating material is provided.

In the n-type silicon substrate 3, extension layers 13 and source/drain regions 15 are provided as p-type high-concentration impurity regions on both sides of the gate electrode 8. On each of the source/drain regions 15, a contact electrode 16 made of nickel (Ni) silicide is provided.

In the third embodiment, erbium (Er) existing on the electrode side of the interface is bonded to oxygen of the upper layer of the gate insulating film 4 located just below the one atomic layer 21 to form an Er—O—Si bond at the interface. Rare-earth metals typified by erbium (Er) are quickly oxidized even at room temperature in the air, that is, they are very easily bonded to oxygen. Therefore, Er is preferentially bonded to oxygen rather than Ni and Si constituting the gate electrode 8 to form an Er—O bond that is a very strong bond. The electronegativity values of rare-earth metals are smaller than those of the constituent elements (Ni and Si) of the gate electrode 8, and therefore an Er—O bond polarizes charge distribution toward a direction opposite to that of the case of the first embodiment where a nonmetallic element is added, that is, toward the gate insulating film side so that an electric dipole is modulated. As a result, the effective work function φ_{eff} of the gate electrode 8 of the third embodiment is modulated so as to be larger as compared to a case where erbium (Er) is not added. As described above, according to the third embodiment, by providing the one atomic layer 21 containing erbium (Er) at an interface between the gate electrode 8 and the gate insulating film 4, it is possible to achieve a metal gate structure which can be applied to MISFET devices having different operating threshold voltages in spite of the fact that only one metal material is used for gate electrodes of the MISFET devices.

FIG. 12 is a graph which shows modulation effect obtained by adding an additive element in a case where NiSi is used as a gate electrode. As can be seen from FIG. 12, only by adding erbium (Er) to the interface at a areal density of 1×10¹⁴ cm⁻² or less, it is possible to achieve a modulation width of effective work function Φ_{eff} of 1 eV or more.

An element to be added to the interface is not limited to erbium (Er). By adding any of the elements mentioned below to the interface, the effect of modulating the effective work function is further enhanced. Therefore, it is possible to easily achieve the amount of modulation of the effective work function φ_{eff} corresponding to a silicon band gap. For example, in a case where an element having a smaller electronegativity than that of erbium (Er) is used, the amount of modulation of the effective work function Φ_{eff} is larger than that of a case where erbium (Er) is added to the interface in substantially the same amount. That is, by using an element having a smaller electronegativity than that of erbium (Er), such as cesium (Cs), strontium (Sr), barium (Ba) or rubidium (Rb), it is possible to achieve substantially the same amount of modulation of the effective work function that is achieved by adding erbium (Er), even when the density of such an additive element added to the interface is smaller than that of erbium (see FIG. 12). For example, in a case where rubidium (Rb) is used as an additive element, it is possible to achieve substantially the same amount of modulation of the effective work function Φ_{eff} that is achieved by adding erbium (Er), even when the amount of rubidium added to the interface is about half that of erbium (Er). Further, even in a case where an element having a smaller electronegativity than that of erbium (Er) is used, the element cannot easily diffuse in the gate insulating film as long as it has a relatively large atomic radius. Therefore, in a case where such an element is added to the interface in the same amount as erbium (Er), a larger amount of the element can be localized in the first atomic layer adjacent to the interface so that it is possible to easily add a high concentration of the element to the first atomic layer provided on the electrode side of the interface, thereby easily enabling the effective work function Φ_{eff} to be modulated. In the third embodiment, by using an element having a larger atomic radius than that of erbium (Er) instead of erbium (Er), it is possible to obtain a larger modulation effect.

As in the case of the first embodiment, the third embodiment also utilizes a difference in electronegativity between an additive element and an element constituting the gate electrode. Therefore, in a case where an element constituting the gate electrode is different from that of the third embodiment, the quantitative relation between the amount of modulation and the amount of an impurity added to the interface is not necessarily the same as that shown in FIG. 12. That is, in contrast to the first embodiment, in a case where the gate electrode is composed of an element having a smaller electronegativity, a difference in electronegativity between each of the elements shown in FIG. 12 and the element constituting the gate electrode becomes smaller so that modulation effect is smaller than that shown in FIG. 12. On the other hand, in a case where the gate electrode is composed of an element having a larger electronegativity, modulation effect is larger than that shown in FIG. 12. Further, even in a case where an element having a larger electronegativity than those of the elements shown in FIG. 12, it is possible to obtain modulation effect as long as the element has a smaller electronegativity than that of an element constituting the gate electrode. For example, in a case where NiSi is used as a gate electrode as in the case of the third embodiment, the Pauling's electronegativity values of nickel (Ni) and silicon (Si) are both 1.9, and therefore the use of an additive element having a Pauling's electronegativity smaller than 1.9 makes it possible to obtain the effect as shown in FIG. 12.

Also in the third embodiment, the gate electrode and its interface with the insulating film are all made of a metal as in the case of the first embodiment, and therefore it is possible to completely eliminate negative effects associated with depletion which occurs when a high-concentration silicon layer is used as a gate electrode.

Further, the metal electrode may contain an element (in the third embodiment, an erbium (Er) atom) which forms an electric dipole in the first atomic layer adjacent to the interface, as long as the concentration of the element is low. However, the average atomic density of the element in the entire gate electrode must be about 10 atomic % or less of a metal mainly constituting the gate electrode so that the element does not affect the work function of the metal. Such a trace amount of the impurity element does not exhibit properties as a bulk, and the charge effect of the impurity element is completely shielded by free electrons in the metal.

It should be noted that the amount of an impurity added to the interface can never exceed the areal density of the metal constituting the gate electrode. If the amount of an impurity added to the first atomic layer adjacent to the interface exceeds the areal density of the metal of the gate electrode, the effective work function Φ_{eff} which determines the threshold voltage of the transistor becomes the work function of bulk of the added element so that it is impossible to control the effective work function with the help of modulation effect of an interface electric dipole. As long as the additive element shown in FIG. 12 is used, it is possible to achieve a modulation amount of 1 eV, even when the amount of such an element added to the interface is one or more orders of magnitude smaller than the areal density of the metal of the gate electrode, that is, it is possible to obtain a sufficient modulation effect without such a problem described above.

In the third embodiment, Ni silicide is used as the gate electrode, but an optimum material for the electrode can be appropriately selected according to the operating threshold voltage of the transistor and a manufacturing process. Particularly, by selecting a noble metal-based material, it is possible to enhance the effect of modulating the effective work function Φ_{eff} because a difference in electronegativity between the rare-earth metal and the noble metal is large. In addition, adhesion of the interface is improved. Further, by using the structure according to the third embodiment, a noble metal electrode having an effective work function Φ_{eff} appropriate to an n-type MIS transistor can also be used for a p-type MOS transistor, and therefore it is possible to significantly simplify the manufacturing process of an LSI including transistors of both conductivity types on the same substrate, such as a CMIS device.

In the third embodiment, since an additive element for modulating an interface electric dipole is added on the electrode side of the interface, the reliability of the gate insulating film is not impaired and the permittivity of the gate insulating film is not changed.

As has been described above, according to the third embodiment, it is possible to control the effective work function of the gate electrode so that the transistor can have an optimum operating threshold voltage.

### Fourth Embodiment

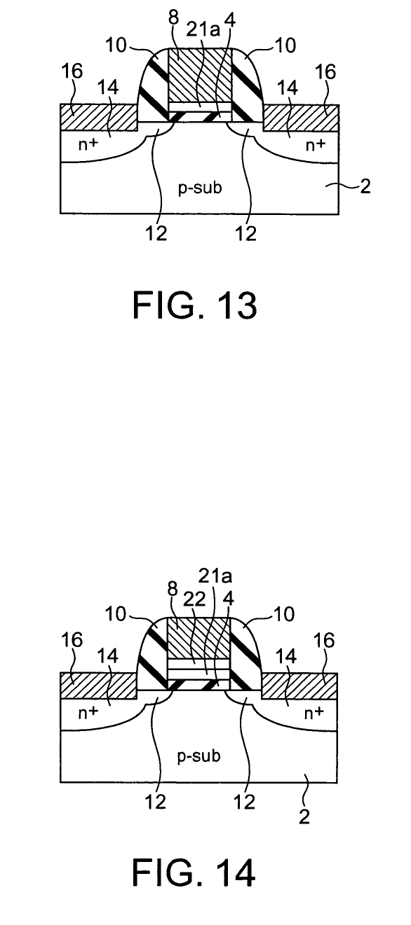

FIG. 13 shows a semiconductor device according to a fourth embodiment of the present invention. The semiconductor device according to the fourth embodiment is an n-type MOS transistor, and has the same structure as the semiconductor device according to the first embodiment shown in FIG. 1 except that the one atomic layer 5 containing phosphorus (P) and provided on the gate electrode side of an interface between the gate electrode 8 and the gate insulating film 4 is replaced with a layer 21a obtained by adding erbium (Er) at a density of one atomic layer or less on the gate insulating film side of the interface. The areal density of erbium (Er) of the one atomic layer 21a is 1×10¹³ cm⁻² or more but 1×10¹⁵ cm⁻² or less.

In the fourth embodiment, erbium (Er) exists in the second or deeper atomic layers from the interface which are provided on the gate insulating film side of the interface through oxygen, and all of the bonds of each erbium (Er) are bonded to oxygen because an Er—O bond is very strong. By adding erbium (Er), an electric dipole opposite in direction to that of the third embodiment is formed at the interface, and as a result the effective work function Φ_{eff} of the gate electrode is modulated to become small. The reason for this is as follows. Erbium (Er) existing in the second layer from the interface through oxygen is bonded to oxygen to form a Ni—O—Er bond or a Si—O—Er bond (the Si is an element constituting the gate electrode). The electronegativity of erbium (Er) is smaller than that of silicon (Si) constituting the gate insulating film, and therefore in the fourth embodiment, a larger amount of electrons exist on the gate electrode side of the interface as compared to a case where erbium (Er) is not inserted into the gate insulating film side of the interface. By virtue of the effect of such an interface electric dipole, the effective work function Φ_{eff} becomes smaller than the work function of the metal of the electrode (in the fourth embodiment, NiSi). Namely, in a case where a gate insulating film interface of a MOS device has such a structure described above, the flat band voltage (Vfb) and the operating threshold voltage of the MOS device are largely modulated toward the negative side as compared to a case where an additive element is not added. In this case, the absolute value of the amount of modulation of the effective work function Φ_{eff} is the same as that of the third embodiment shown in FIG. 12 in a case where SiO₂ is used as the gate insulating film.

As in the case of the third embodiment, if the assumption is made that the amount of an additive element added to the interface is the same, by using an alkali metal or an alkaline-earth metal as an additive element so that the effect of an interface electric dipole is further enhanced, it is possible to obtain a larger modulation effect. The additive element preferably has a relatively large atomic radius because such an additive element is not easily diffused due to heat treatment. Further, the additive element may be distributed not only in the second atomic layer from an interface between the gate electrode and the gate insulating film through oxygen of the first atomic layer provided on the insulating film side of the interface but also in the gate insulating film to a certain extent. In this case, each of the electric dipoles obtained by the additive element and existing in the third or deeper atomic layers is canceled out, and therefore the effect of modulating an effective work function Φ_{eff} is not impaired. However, the additive element distributed in an area closer to a channel region serves as a scatterer for carriers in the channel, and interferes with the operation of the device. Therefore, it is usually required that the areal density of the additive element existing at an interface between the insulating film and the silicon substrate be 1×10¹² cm⁻² or less. If the additive element is added to the electrode side of the interface, the effect of an electric dipole becomes small, which is not advantageous from the viewpoint of modulation of the effective work function Φ_{eff}. However, in a case where a metal that is poor in adhesion with the insulating film, such as a noble metal, is used for the electrode, erbium (Er) added to the electrode side of the interface is bonded to oxygen located on the gate insulating film side so that adhesion between the electrode and the insulating film is improved. FIG. 14 shows a semiconductor device according to a first modification of the fourth embodiment. This semiconductor device has a layer 22 containing erbium (Er) at a density of one atomic layer or less and provided on the gate electrode side of an interface between a gate electrode and an insulating film. The layer 22 contains erbium (Er) at a areal density that is one order of magnitude smaller than the areal density of the additive element existing in the layer 21a provided on the insulating film side of the interface. It can be said that such a structure is more advantageous because it is possible to improve adhesion of the interface while keeping the effect of modulating an effective work function Φ_{eff}.

As a metal for the gate electrode, transition metals that are excellent in adhesion with the gate insulating film or compounds thereof are preferably used. However, as described above, it becomes possible to use a noble metal as a material for the gate electrode by allowing a trace amount of an additive element to exist on the electrode side of the interface. The areal density of a substance segregated at the interface is appropriately adjusted according to the work function of the metal. In such a case, by using the structure according to the fourth embodiment, a noble metal having an effective work function Φ_{eff} appropriate to a p-type MIS transistor can also be used for an n-type MOS transistor, and therefore it is possible to significantly simplify the manufacturing process of an LSI including transistors of both conductivity types on the same substrate, such as a CMIS device.

In a case where a high-k film other than SiO₂ is used as the gate insulating film, it is necessary to use a rare-earth, alkali metal or alkaline-earth metal element having a smaller electronegativity than that of an element constituting the high-k film. Further, in a case where an insulating film containing an element having a relatively large electronegativity (e.g., nitrogen), such as HfSiON is used, a larger modulation effect can be obtained.

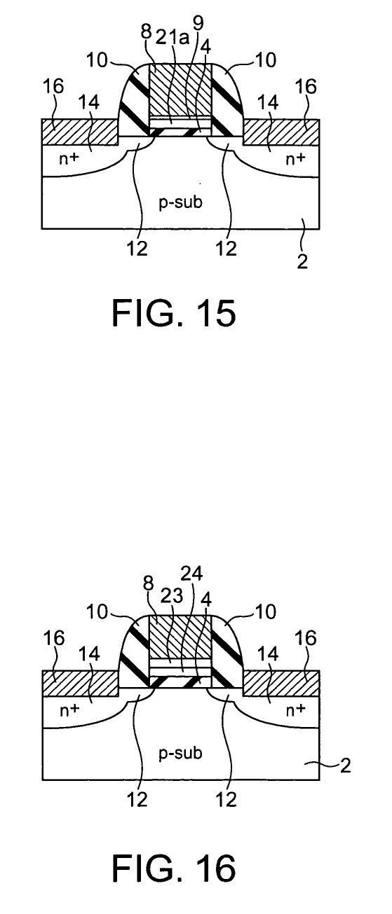

FIG. 15 shows a semiconductor device according to a second modification of the fourth embodiment. The semiconductor device has a layer 21a provided immediately above a gate insulating film 4 and containing erbium (Er) as an additive element at a density of one atomic layer or less. On the layer 21a, a layer 9 obtained by adding oxygen at a density of one atomic layer is provided. On the layer 9, a gate electrode 8 made of a metal is provided. As in the case of the fourth embodiment, an Er—O—Si bond, that is, an electric dipole exists at an interface between the gate electrode and the gate insulating film.

In this modification, it is possible to control an effective work function Φ_{eff} without adversely affecting channel mobility because erbium (Er) is added only to the layer 21a. In this case, from the viewpoint of adhesion between the gate electrode and the gate insulating film, preferred examples of a material for the electrode include transition metal elements and compounds thereof.

In the fourth embodiment and the modifications of the fourth embodiment, Ni silicide is used as the gate electrode, but an optimum material for the electrode can be appropriately selected according to the operating threshold voltage of the transistor and a manufacturing process. The effective work function modulation effect obtained by adding an additive element does not depend on an element constituting the electrode. Particularly, a noble metal electrode having an effective work function Φ_{eff} appropriate to an n-type MIS transistor can also be used for the p-type MOS transistors according to the fourth embodiment and the modifications of the fourth embodiment, and therefore it is possible to significantly simplify the manufacturing process of an LSI including transistors of both conductivity types on the same substrate, such as a CMIS device.

As has been described above, according to the fourth embodiment, it is possible to control the effective work function of the gate electrode so that the transistor can have an optimum operating threshold voltage.

### Fifth Embodiment

FIG. 16 shows a semiconductor device according to a fifth embodiment of the present invention. The semiconductor device according to the fifth embodiment is an n-type MOS transistor, and has the same structure as the semiconductor device according to the first embodiment shown in FIG. 1 except that the one atomic layer 5 containing phosphorus (P) at a density of one atomic layer or less and provided on the gate electrode side of an interface between the gate electrode 8 and the gate insulating film 4 is replaced with a one atomic layer 23 obtained by adding fluorine (F) at a density of one atomic layer or less and that a layer 24 is provided by adding rubidium (Rb) on the gate insulating film side of the interface at a density of one atomic layer or less so that rubidium is bonded to an element of the gate electrode through oxygen. The areal density of fluorine (F) of the one atomic layer 23 is 1×10¹³ cm⁻² or more but 1×10¹⁵ cm⁻² or less. The areal density of rubidium (Rb) of the layer 24 is 1×10¹³ cm⁻² or more but 1×10¹⁵ cm⁻² or less.

In the fifth embodiment, as described above, nonmetallic atoms (fluorine (F)) having a relatively large electronegativity are added to the gate electrode side of an interface between the gate electrode and the gate insulating film, and a rare-earth metal element (rubidium (Rb)) having a relatively small electronegativity is added to the gate insulating film side of the interface so that rubidium is bonded to an element of the gate electrode through oxygen. As in the cases of the first and third embodiments, addition of such elements makes the effective work function Φ_{eff} of the gate electrode smaller as compared to a case where no element is added. Further, since these two elements have their respective individual effects, by using these two elements together, it is possible to obtain a larger modulation effect. In this case, even when the density of each of the elements added to both sides of an interface between the gate electrode and the gate insulating film is substantially the same as that in the case of the first and third embodiments, it is possible to achieve a larger amount of modulation. The kind of additive element is selected based on the guidelines described with reference to the above embodiments according to a required amount of modulation and subsequent processes.

As has been described above, according to the fifth embodiment, it is possible to control the effective work function of the gate electrode so that the transistor can have an optimum operating threshold voltage.

### Sixth Embodiment

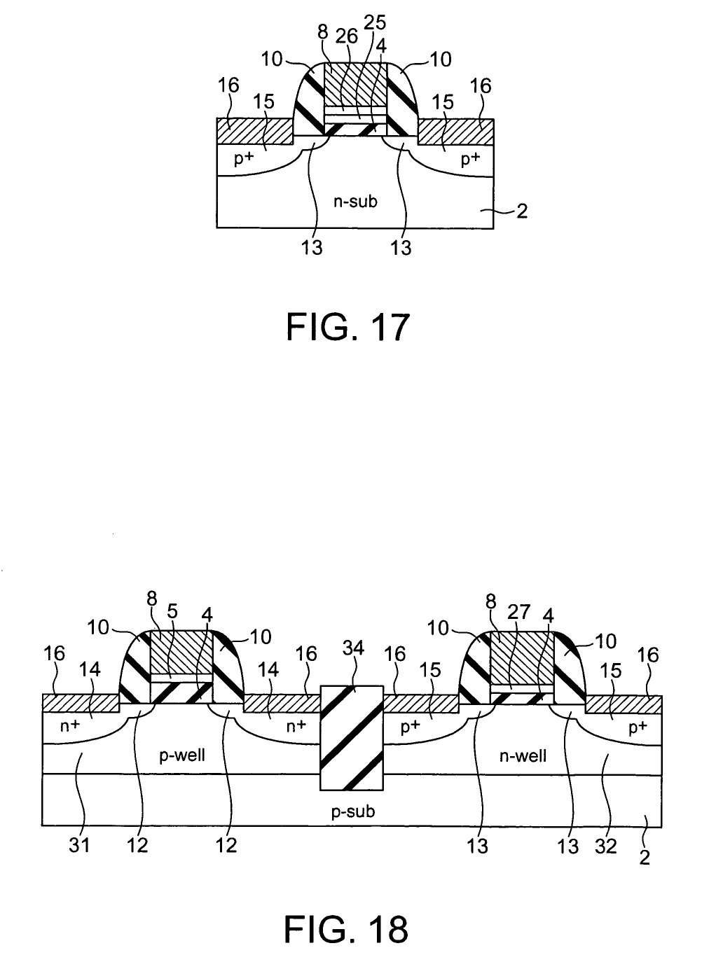

FIG. 17 shows a semiconductor device according to a sixth embodiment of the present invention. The semiconductor device according to the sixth embodiment is a p-type MOS transistor, and has the same structure as the semiconductor device according to the second embodiment shown in FIG. 6 except that the layer 6 containing boron (B) at a density of one atomic layer or less and provided on the gate insulating film side of an interface between the gate electrode 8 and the gate insulating film 4 is replaced with a layer 25 obtained by adding carbon (C) at a density of one atomic layer or less so that carbon is bonded to an element of the gate electrode through oxygen, and that a one atomic layer 26 is provided by adding indium (In) on the gate electrode side of the interface at a density of one atomic layer or less. The areal density of In (Indium) of the one atomic layer 26 is 1×10¹³ cm⁻² or more but 1×10¹⁵ cm⁻² or less. The areal density of carbon (C) of the layer 25 is 1×10¹³ cm⁻² or more but 1×10¹⁵ cm⁻² or less.

In the sixth embodiment, as described above, nonmetallic atoms (carbon (C)) having a relatively large electronegativity are added to the gate insulating film side of the interface so that carbon is bonded to an element of the gate electrode through oxygen, and an alkali metal, alkaline-earth metal or rare-earth metal element (Indium (In)) having a relatively small electronegativity is added to the gate electrode side of the interface. As described in the first to fourth embodiments, addition of such elements makes the effective work function φ_{eff} of the gate electrode larger as compared to a case where no element is added. Further, since these two elements added to both sides of the interface have their respective individual effects, by using these two elements together, it is possible to obtain a larger modulation effect. In this case, even when the density of each of the elements added to both sides of the interface is substantially the same as that in the case of the first and third embodiments, it is possible to achieve a larger amount of modulation. The kind of additive element is selected based on the guidelines described with reference to the above embodiments according to a required amount of modulation and subsequent processes.

As has been described, according to the sixth embodiment, it is possible to control the effective work function of the gate electrode so that the transistor can have an optimum operating threshold voltage.

### Seventh Embodiment

FIG. 18 shows a semiconductor device according to a seventh embodiment of the present invention. The semiconductor device has a structure in which an n-type MIS transistor having the same structure as the first embodiment is provided on a p-type well 31 of a p-type silicon substrate 2 and a p-type MIS transistor having the same structure as the second embodiment is provided on an n-type well 32. Although the gate electrode 8 of each of the n-type and p-type MIS transistors is made of Ni silicide, an optimum metal can be appropriately selected according to a device generation.

Further, although the position to which an additive element is added is different between the n-type and p-type MIS transistors, phosphorus (P) is added as an additive element to an interface between the gate electrode 8 and the gate insulating film 4 irrespective of the conductivity type of the MIS transistors. The maximum areal density of phosphorus of the first atomic layer adjacent to the interface is 1×10¹³ cm⁻² or more but 1×10¹⁵ cm⁻² or less. More specifically, the n-type MIS transistor provided on the p-type well 31 has a one atomic layer 5 obtained by adding phosphorus (P) to the gate electrode side of the interface at a density of one atomic layer or less, and the p-type MIS transistor provided on the n-type well 32 has a layer 27 obtained by adding phosphorus (P) to the gate insulating film side of the interface at a density of one atomic layer or less so that phosphorus is bonded to an element constituting the gate electrode 8 through oxygen.

The additive element may be appropriately changed to any of the elements mentioned in the first and second embodiments, and the density of the additive element may also be appropriately changed according to the operating voltage of the device. The n-type MIS transistor and the p-type MIS transistor are separated from each other by an element isolation region 34 formed from a silicon oxide film. Each of these two transistors operates complimentary, and constitutes a CMIS device.

A CMIS device to be used in a semiconductor device for logical computing needs to operate at high speed and low voltage. Therefore, transistors of different conductivity types have to have different effective work function values Φ_{eff}. Further, the operating voltage of such a CMIS device varies depending on the purpose of use of a semiconductor device, and therefore it is desired that the effective work function Φ_{eff} of each of the gate electrodes be continuously controlled in an amount corresponding to a silicon band gap according to the purpose of use of the semiconductor device. In the seventh embodiment, the effective work function Φ_{eff} of the gate electrode of the n-type MIS transistor is adjusted to an optimum value for device operation by adding a nonmetallic element (phosphorus (P)) to the gate electrode side of the interface as in the case of the first embodiment. On the other hand, the effective work function Φ_{eff} of the gate electrode of the p-type MIS transistor is adjusted to an optimum value for device operation by adding a nonmetallic element (phosphorus (P)) to the gate insulating film side of the interface as in the case of the second embodiment.

According to the seventh embodiment, it is possible to simplify the manufacturing process of the CMIS device and to significantly reduce costs for development of the CMIS device because both of the gate electrodes of the transistors of different conductivity types can be made of the same metal material and the same additive element can be added to the interface in both of the transistors. Further, by simply changing the position to which the additive element is added according to the conductivity type of the transistor, it is possible to control the effective work function Φ_{eff} of the gate electrode so that the transistor can have an optimum threshold voltage.

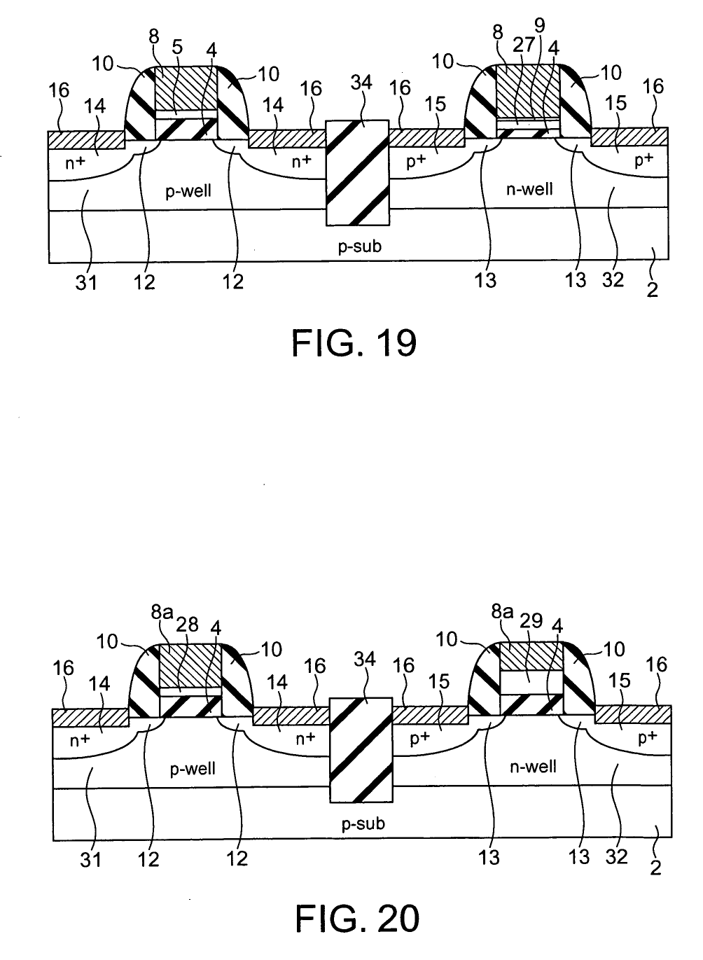

FIG. 19 shows a semiconductor device according to a modification of the seventh embodiment. The semiconductor device according to the modification of the seventh embodiment has the same structure as the semiconductor device according to the seventh embodiment except that a one atomic layer 9 obtained by adding oxygen at a density of one atomic layer is provided on the layer 4 of the p-type MIS transistor.

Also in the case of this modification, it is possible to control the effective work function of the gate electrode so that the transistor can have an optimum operating threshold voltage as in the case of the seventh embodiment.

### Eighth Embodiment

FIG. 20 shows a semiconductor device according to an eighth embodiment of the present invention. The semiconductor device according to the eighth embodiment has a structure in which an n-type MIS transistor is provided on a p-type well 31 of a p-type silicon substrate 2 and a p-type MIS transistor is provided on an n-type well 32. The n-type MIS transistor has the same structure as the n-type MIS transistor according to the first embodiment except that the layer 5 containing phosphorus (P) and provided on the gate electrode side of an interface of the gate electrode 8 and the gate insulating film 4 is replaced with a one atomic layer 28 obtained by adding carbon (C) to the gate electrode side of the interface at a areal density of 1×10¹³ cm⁻² or more but 1×10¹⁵ cm⁻² or less and that the gate electrode 8 made of Ni silicide is replaced with a gate electrode 8a made of tantalum (Ta) silicide.

As described above, the n-type MIS transistor according to the eighth embodiment is different from the n-type MIS transistor according to the first embodiment in the metal material of the gate electrode and the additive element, but the effective work function Φ_{eff} of Ta silicide of the gate electrode 8a is modulated by carbon (C) added to the interface so that the effective work function becomes small.

On the other hand, the p-type MIS transistor according to the eighth embodiment has a structure in which a gate electrode having a laminated structure is provided on a gate insulating film 4 formed from a thermally-oxidized silicon film having a thickness of 2 nm or less. The gate electrode is composed of an upper layer 8a and a lower layer 29. The upper layer 8a is made of tantalum (Ta) silicide that is also used for the electrode of the n-type MIS transistor, and the lower layer 29 is made of Ta carbide that is a compound of tantalum (Ta) and carbon (C). Ta carbide has a larger work function than that of Ta silicide. Specifically, Ta carbide has a work function value of 4.7 eV to 5.1 eV required for a p-type MIS transistor. The thickness of the layer of Ta carbide is not particularly limited as long as it is one atomic layer or more. However, since the resistivity of Ta carbide is larger than that of Ta silicide, it is preferred that the thickness of the layer of Ta carbide is as small as possible. In the n-type well 32, extension layers 13 and source/drain regions 15 are provided as p-type high-concentration impurity regions on both sides of the gate insulating film 4. On each of the source/drain regions 15, a contact electrode 16 made of Ni silicide is provided. The n-type MIS transistor and the p-type MIS transistor are separated from each other by an element isolation region 34 formed from a silicon oxide film. Each of these MIS transistors operates complimentary, and constitutes the CMIS device.

In each of the transistors, elements constituting the gate electrode are tantalum (Ta), silicon (Si), and carbon (C). However, by changing the structure of the gate electrode and controlling the amount of carbon to be added to the interface according to the conductivity type of the transistor, it is possible to adjust the effective work function Φ_{eff} of the interface to an optimum value. Further, in each of the transistors, a metal element constituting the gate electrode is Ta, but it is possible to appropriately select an optimum metal according to a device generation. The additive element may be appropriately changed to any of the elements mentioned in the first and second embodiments, and the density of the additive element may also be appropriately changed according to the operating voltage of the device.

According to the eighth embodiment, it is possible to simplify the manufacturing process of the CMIS device and to significantly reduce costs for development of the CMIS device because the gate electrodes of both of the transistors are composed of the same elements.

In addition, according to the eighth embodiment, it is also possible to eliminate factors that deteriorate transistor characteristics, such as deterioration of the gate insulating film due to addition of carbon (C) and decrease in mobility due to increase in the number of fixed charges, because carbon (C) as an additive element is added to the gate electrode side of the interface irrespective of the conductivity type of the transistor.

AS has been described above, according to the eighth embodiment, it is possible to control the effective work function of the gate electrode so that the transistor can have an optimum operating threshold voltage.

### Ninth Embodiment

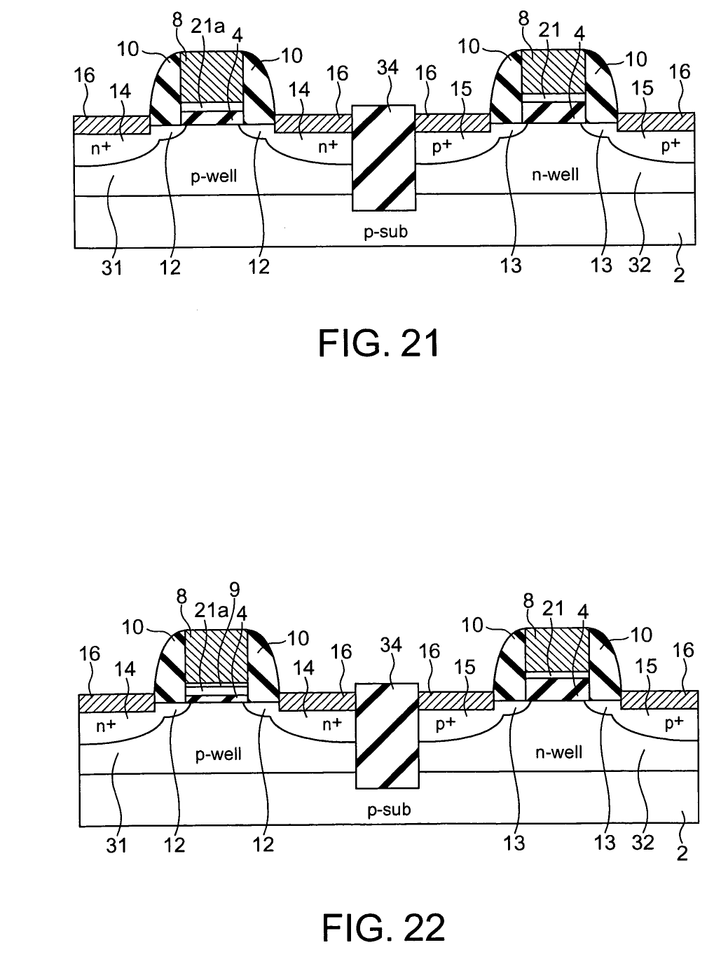

FIG. 21 shows a semiconductor device according to a ninth embodiment of the present invention. The semiconductor device according to the ninth embodiment has a structure in which the n-type MIS transistor according to the fourth embodiment shown in FIG. 13 is provided on a p-type well of a p-type silicon substrate 2 and the p-type MIS transistor according to the third embodiment shown in FIG. 11 is provided on an n-type well.

In the ninth embodiment, the gate electrodes 8 of both of the transistors are made of Ni silicide, but an optimum metal can be appropriately selected according to a device generation. Although the position to which an additive element is added is different between the n-type and p-type MIS transistors, erbium (Er) is added as an additive element to an interface between the gate electrode 8 and the gate insulating film 4 irrespective of the conductivity type of the MIS transistor. The maximum areal density of erbium (Er) at the interface is 1×10¹³ cm⁻² or more but 1×10¹⁵ cm⁻² or less. The additive element may be appropriately changed to any of the elements shown in FIG. 12, and the density of the additive element may also be appropriately changed according to the operating voltage of the device. The n-type MIS transistor and the p-type MIS transistor are separated from each other by an element isolation region 34 formed from a silicon oxide film. Each of these two transistors operates complimentary, and constitutes the CMIS device.

In the ninth embodiment, the effective work function φ_{eff} of the gate electrode of the p-type MIS transistor is adjusted to an optimum value for device operation by adding a rare-earth element, erbium (Er) to the gate electrode side of the interface as in the case of the third embodiment. On the other hand, the effective work function Φ_{eff} of the gate electrode of the n-type MIS transistor is adjusted to an optimum value for device operation by adding a rare-earth element, erbium (Er) to the gate insulating film side of the interface as in the case of the fourth embodiment. As described above, in the ninth embodiment, the gate electrodes of both of the MIS transistors of different conductivity types are made of the same metal material, and the same additive element is used for both of the MIS transistors. Therefore, by simply changing the position to which the additive element is added according to the conductivity type of the transistor, it is possible to freely control the effective work function Φ_{eff} of the interface.

Therefore, as in the case of the seventh embodiment, it is possible to simplify the manufacturing process of the CMIS device and to significantly reduce costs for development of the CMIS device and to control the effective work function of the gate electrode so that the transistor can have an optimum operating threshold voltage.

FIG. 22 shows a semiconductor device according to a modification of the ninth embodiment. The semiconductor device according to the modification of the ninth embodiment has the same structure as the semiconductor device according to the ninth embodiment except that the n-type MIS transistor provided on the p-type well is replaced with the n-type MIS transistor according to the second modification of the fourth embodiment shown in FIG. 15. As in the case of the ninth embodiment, this modification makes it possible to simplify the manufacturing process of the CMIS device and to significantly reduce costs for development of the CMIS device and to control the effective work function of the gate electrode so that the transistor can have an optimum operating threshold voltage.

### Tenth Embodiment

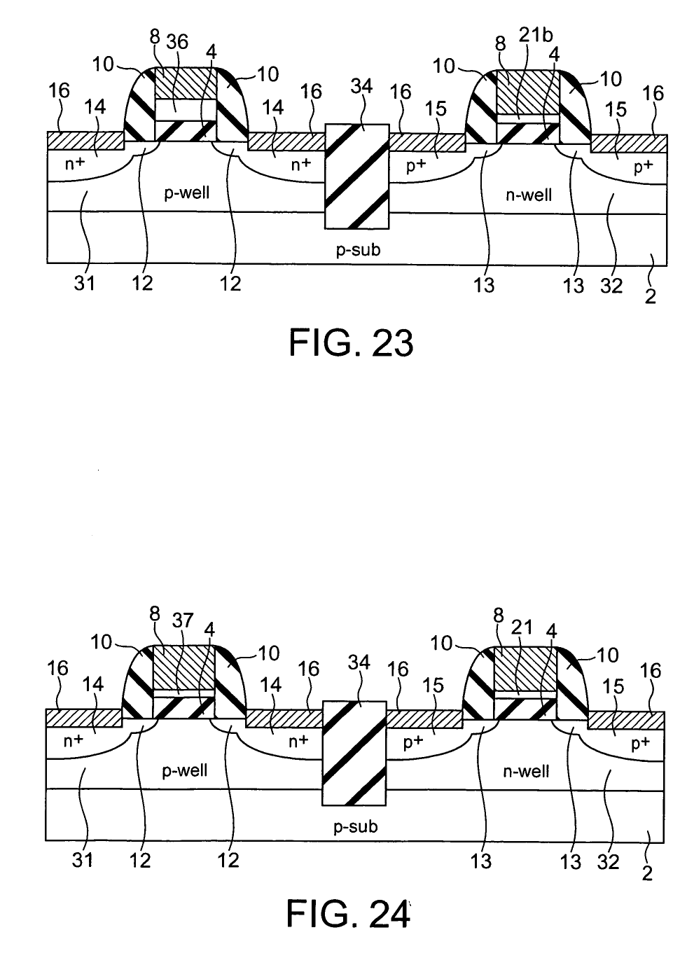

FIG. 23 shows a semiconductor device according to a tenth embodiment of the present invention. The semiconductor device according to the tenth embodiment has a structure in which the p-type MIS transistor according to the third embodiment shown in FIG. 11 is provided on a n-type well 32 of a p-type silicon substrate 2 and an n-type MIS transistor is provided on a p-type well 31. As in the case of the fourth embodiment, the effective work function Φ_{eff} of Ni silicide of the gate electrode of the p-type MIS transistor is modulated by erbium (Er) added to an interface between the gate electrode and the gate insulating film so that the effective work function becomes large.

On the other hand, the n-type MIS transistor provided on the p-type well 31 has a structure in which a gate insulating film 4 formed from a thermally-oxidized silicon film having a thickness of 2 nm or less is provided on the p-type well 31, and a gate electrode having a laminated structure is provided on the gate insulating film 4. The gate electrode is composed of an upper layer 8 and a lower layer 36. The upper layer 8 is made of Ni suicide that is also used for the electrode of the p-type MIS transistor, and the lower layer 36 is made of Er silicide that is a compound of erbium (Er) and silicon (Si). Er silicide has an effective work function Φ_{eff} corresponding to a value close to the conduction band edge Ec of silicon (3.7 eV to 4.0 eV). Such an effective work function is advantageous to the gate electrode of the n-type MIS transistor. The thickness of the layer of Er suicide is not particularly limited as long as it is one atomic layer or more. However, since the resistivity of Er silicide is larger than that of Ni silicide, it is preferred that the thickness of the layer of Er suicide is as small as possible. In the p-type well 31, extension layers 12 and source/drain regions 14 are provided as n-type high-concentration impurity regions on both sides of the gate insulating film 4. On each of the source/drain regions, a contact electrode 16 made of Ni silicide is provided.

The n-type MIS transistor and the p-type MIS transistor are separated from each other by an element isolation region 34 formed from a silicon oxide film. Each of these two transistors operates complimentary, and constitutes the CMIS device.

In each of the p-type and n-type MIS transistors, elements constituting the gate electrode are nickel (Ni), silicon (Si), and erbium (Er). However, by changing the structure of the gate electrode and controlling the amount of erbium to be added to the interface according to the conductivity type of the transistor, it is possible to adjust the effective work function φ_{eff} of the interface to an optimum value. Therefore, it is possible to control the effective work function of the gate electrode so that the transistor can have an optimum operating threshold voltage.

Further, in each of the transistors, erbium (Er) is used as an additive element, but the additive element may be appropriately changed to an optimum metal having a relatively small electronegativity, such as any of the elements mentioned in FIG. 12, according to a device generation, and the density of the additive element may also be appropriately changed according to the operating voltage of the device.

According to the tenth embodiment, it is possible to simplify the manufacturing process of the CMIS device and to significantly reduce costs for development of the CMIS device because the gate electrodes of both of the p-type and n-type MIS transistors are composed of the same elements.

In addition, according to the tenth embodiment, it is also possible to eliminate factors that deteriorate transistor characteristics, such as deterioration of the gate insulating film due to addition of erbium (Er) and decrease in mobility due to increase in the number of fixed charges, because erbium (Er) as an additive element is added to the gate electrode side of the interface irrespective of the conductivity type of the transistor.

### Eleventh Embodiment

FIG. 24 shows a semiconductor device according to an eleventh embodiment of the present invention. The semiconductor device according to the eleventh embodiment has a structure in which an n-type MIS transistor is provided on a p-type well 31 of a p-type silicon substrate 2 and a p-type MIS transistor having the same structure as the semiconductor device according to the third embodiment shown in FIG. 11 is provided on an n-type well 32. The n-type MIS transistor has the same structure as the n-type MIS transistor according to the first embodiment shown in FIG. 1 except that the one atomic layer 5 containing phosphorus (P) and provided as the first atomic layer on the electrode side of an interface between the gate electrode 8 and the gate insulating film 4 is replaced with a one atomic layer 37 containing nitrogen (N) at a density of one atomic layer or less.

In the n-type MIS transistor, the areal density of nitrogen added to the interface is 1×10¹³ cm⁻² or more but 1×10¹⁵ cm⁻² or less. In the p-type MIS transistor, the areal density of erbium (Er) added to the interface is 1×10¹³ cm⁻² or more but 1×10¹⁵ cm⁻² or less.

Although the gate electrode of each of the n-type and p-type MIS transistors is made of Ni silicide, an optimum metal can be appropriately selected according to a device generation. From the viewpoint of the control of effective work function Φ_{eff} of the gate electrode, a metal or a metal compound with a Fermi level at the center of the forbidden band of silicon is preferably used.

The additive element, nitrogen (N) may be appropriately changed to any of the elements shown in FIG. 5, and the additive element, erbium (Er) may be appropriately changed to any of the elements shown in FIG. 12. Further, the density of each of the additive elements may also be appropriately changed according to the operating voltage of the device. The n-type and p-type MIS transistors are separated from each other by an element isolation region 34 formed from a silicon oxide film. Each of these two transistors operates complimentary, and constitutes the CMIS device.

As in the cases of the first embodiment and the third embodiment, by adding the impurity element to the gate electrode side of the interface in each of the n-type and p-type MIS transistors, it is possible to control the effective work function of the gate electrode so that the transistor can have an optimum operating threshold voltage.

Particularly, according to the eleventh embodiment, the additive element is added to the gate electrode side of the interface irrespective of the conductivity type of the transistor, and therefore factors that deteriorate transistor characteristics, such as deterioration of the gate insulating film and decrease in mobility due to increase in the number of fixed charges are not present in the gate insulating film. The additive element added to the n-type MIS transistor and the additive element added to the p-type MIS transistor may be appropriately changed to any of the elements mentioned in the first embodiment and any of the elements mentioned in the third embodiment, respectively. Further, the density of each of the additive elements may also be appropriately changed according to the operating voltage of the device. The change of the effective work function Φ_{eff} achieved by adding the additive element does not depend on the insulating film provided below the gate electrode. Therefore, it is possible to form the gate electrode structure completely independently of the material and structure of the gate insulating film, that is, it is possible to select a material for the gate electrode irrespective of the material of the gate insulating film.

### Twelfth Embodiment

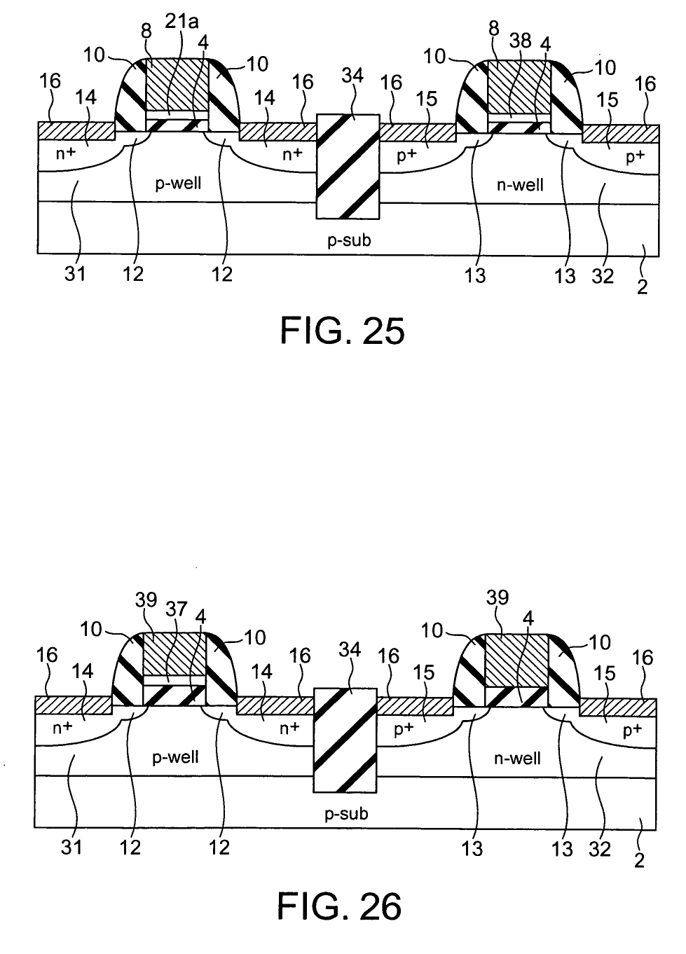

FIG. 25 shows a semiconductor device according to a twelfth embodiment of the present invention. The semiconductor device according to the twelfth embodiment has a structure in which an n-type MIS transistor having the same structure as the semiconductor device according to the fourth embodiment shown in FIG. 13 is provided on a p-type well 31 of a p-type silicon substrate 2 and a p-type MIS transistor is provided on an n-type well 32. The p-type MIS transistor has the same structure as the p-type MIS transistor according to the second embodiment shown in FIG. 6 except that the layer 6 containing boron (B) is replaced with a layer 38 obtained by adding nitrogen (N) to the gate insulating film side of an interface between the gate electrode and the gate insulating film at a density of one atomic layer or less so that nitrogen is bonded to an element constituting the gate electrode through oxygen.

Although the gate electrode of each of the n-type and p-type MIS transistors is made of Ni silicide, an optimum metal can be appropriately selected according to a device generation. From the viewpoint of the control of effective work function Φ_{eff} of the gate electrode, a metal or a metal compound with a Fermi level at the center of the forbidden band of silicon is preferably used. The additive element added to the n-type MIS transistor may be appropriately changed to any of the elements shown in FIG. 12, and the additive element added to the p-type MIS transistor may be appropriately changed to any of the elements shown in FIG. 5. Further, the density of each of the additive elements may also be appropriately changed according to the operating voltage of the device.

The n-type and p-type MIS transistors are separated from each other by an element isolation region 34 formed from a silicon oxide film. Each of these two transistors operates complimentary, and constitutes the CMIS device.

As in the cases of the fourth embodiment and the second embodiment, by adding the impurity element to the gate insulating film side of the interface in each of the n-type and p-type MIS transistors, it is possible to control the effective work function of the gate electrode so that the transistor can have an optimum operating threshold voltage.

Particularly, in the n-type MIS transistor according to the twelfth embodiment, a rare-earth metal element is added to the gate insulating film, and therefore the permittivity of the gate insulating film is increased so that device characteristics are improved. On the other hand, in the p-type MIS transistor, nitrogen (N) is present in the vicinity of the interface, and therefore it is possible to suppress diffusion of the metal atoms constituting the gate electrode into the gate insulating film, thereby improving the structural reliability of the gate electrode.

### Thirteenth Embodiment

FIG. 26 shows a semiconductor device according to a thirteenth embodiment of the present invention. The semiconductor device according to the thirteenth embodiment has a structure in which an n-type MIS transistor is provided on a p-type well 31 of a p-type silicon substrate 2 and a p-type MIS transistor is provided on an n-type well 32.

In the n-type MIS transistor, a gate insulating film 4 formed from a thermally-oxidized silicon film having a thickness of 2 nm or less is provided on the p-type well 31, and a gate electrode 39 is provided on the gate insulating film 4. On the gate electrode side of an interface between the gate electrode 39 and the gate insulating film 4, a one atomic layer 37 containing nitrogen (N) at a density of one atomic layer or less is provided. On the side faces of the gate electrode 39, a gate side wall 10 made of an insulating material is provided. In the p-type well 31, extension layers 12 and source/drain regions 14 are provided as n-type high-concentration impurity regions on both sides of the gate electrode 39. On each of the source/drain regions 14, a contact electrode 16 made of Ni silicide is provided.

On the other hand, in the p-type MIS transistor, a gate insulating film 4 formed from a thermally-oxidized silicon film having a thickness of 2 nm or less is provided on the n-type well 32, and a gate electrode 39 is provided on the gate insulating film 4. On the side faces of the gate electrode 39, a gate side wall 10 made of an insulating material is provided. In the n-type well 32, extension layers 13 and source/drain regions 15 are provided as p-type high-concentration impurity regions on both sides of the gate electrode 39. On each of the source/drain regions 15, a contact electrode 16 made of Ni silicide is provided.

In the thirteenth embodiment, the gate electrode 39 is made of a metal or a metal compound having an effective work function Φ_{eff} of more than 4.7 eV, such as Ru, Pt, NiGe or TaC. Therefore, only in the n-type MIS transistor, an element (nitrogen (N)) is added to an interface between the gate electrode and the gate insulating film to adjust the effective work function Φ_{eff} at the interface to 4.6 eV or less with the help of the effect of an interface electric dipole. It is to be noted that the amount of the additive element to be added to the interface must be 1×10¹³ cm⁻² or more but 1×10¹⁵ cm⁻² or less.

As described above, in the thirteenth embodiment, a metal appropriate to the transistor of one conductivity type is used also for the metal gate electrode of the transistor of the other conductivity type, and the additive element is added only to the transistor of the other conductivity type to adjust the effective work function Φ_{eff} of the interface to an optimum value for operation of the transistor. By doing so, it is possible to decrease the number of additive elements to only one. In addition, it is also possible to significantly simplify a manufacturing process as compared to a case where an additive element is added to both of the transistors of different conductivity types because at least one photolithography step and at least one step of adding an additive element can be omitted.

According to the thirteenth embodiment, it is possible to control the effective work function of the gate electrode so that the transistor can have an optimum operating threshold voltage.

### Fourteenth Embodiment

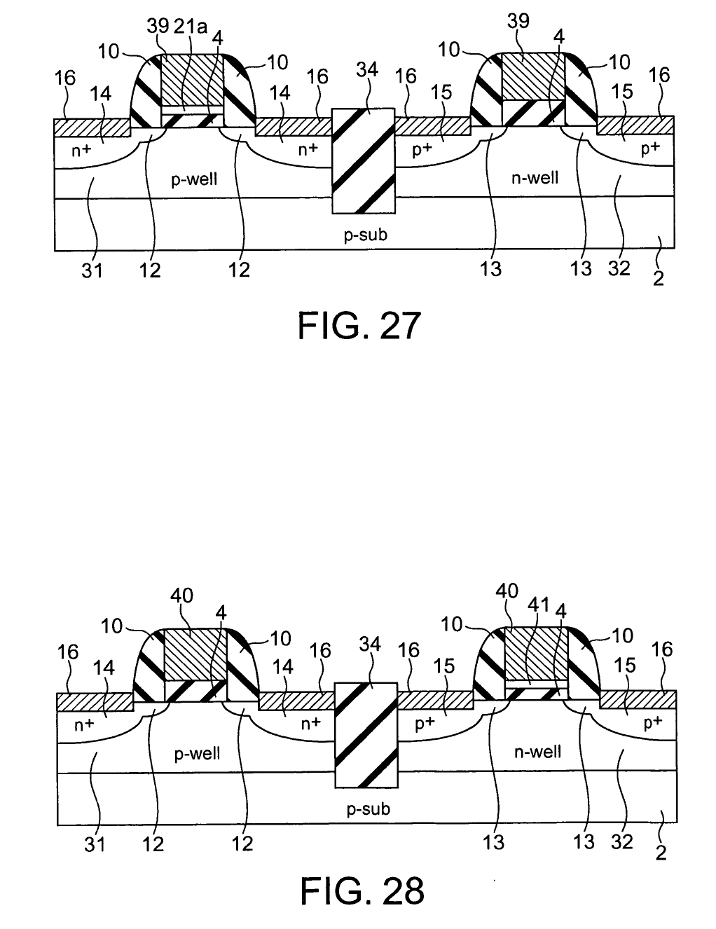

FIG. 27 shows a semiconductor device according to a fourteenth embodiment of the present invention. The semiconductor device according to the fourteenth embodiment has the same structure as the semiconductor device according to the thirteenth embodiment shown in FIG. 26 except that the layer 37 containing nitrogen (N) and provided on the gate electrode side of an interface between the gate electrode and the gate insulating film of the n-type MIS transistor is replaced with a layer 21a obtained by adding erbium (Er) on the gate insulating film side of the interface at a density of one atomic layer or less so that erbium is bonded to an element constituting the gate electrode 39 through oxygen.

As in the case of the thirteenth embodiment, the gate electrode 39 is made of a metal or a metal compound having an effective work function Φ_{eff} of more than 4.7 eV, such as Ru, Pt, NiGe or TaC. Therefore, only in the n-type MIS transistor, an element (nitrogen (N)) is added to an interface between the gate electrode and the gate insulating film to adjust the effective work function Φ_{eff} at the interface to 4.6 eV or less with the help of the effect of an interface electric dipole. It is to be noted that the amount of the additive element to be added to the interface must be 1×10¹³ cm⁻² or more but 1×10¹⁵ cm⁻² or less.

As described above, in the fourteenth embodiment, a metal appropriate to the transistor of one conductivity type is used also for the metal gate electrode of the transistor of the other conductivity type, and the additive element is added only to the transistor of the other conductivity type to adjust the effective work function of the interface to an optimum value for operation of the transistor. By doing so, it is possible to decrease the number of additive elements to only one. In addition, it is also possible to significantly simplify a manufacturing process as compared to a case where an additive element is added to both of the transistors of different conductivity types because at least one photolithography step and at least one step of adding an additive element can be omitted.

According to the fourteenth embodiment, it is possible to control the effective work function of the gate electrode so that the transistor can have an optimum operating threshold voltage.

### Fifteenth Embodiment

FIG. 28 shows a semiconductor device according to a fifteenth embodiment of the present invention. The semiconductor device according to the fifteenth embodiment has a structure in which an n-type MIS transistor is provided on a p-type well 31 of a p-type silicon substrate 2 and a p-type MIS transistor is provided on an n-type well 32.

In the n-type MIS transistor, a gate insulating film 4 formed from a thermally-oxidized silicon film having a thickness of 2 nm or less is provided on the p-type well 31, and a gate electrode 40 is provided on the gate insulating film 4. On the side faces of the gate electrode 40, a gate side wall 10 made of an insulating material is provided. In the p-type well 31, extension layers 12 and source/drain regions 14 are provided as n-type high-concentration impurity regions on both sides of the gate electrode 40. On each of the source/drain regions 14, a contact electrode 16 made of Ni silicide is provided.

On the other hand, in the p-type MIS transistor, a gate insulating film 4 formed from a thermally-oxidized silicon film having a thickness of 2 nm or less is provided on the n-type well 32, and a gate electrode 40 is provided on the gate insulating film 4. Between the gate electrode 40 and the gate insulating film 4, there is provided a layer 41 obtained by adding carbon (C) at a density of one atomic layer or less to the gate insulating film side of the interface so that carbon is bonded to an element of the gate electrode through oxygen. On the side faces of the gate electrode 40, a gate side wall 10 made of an insulating material is provided. In the n-type well 32, extension layers 13 and source/drain regions 15 are provided as p-type high-concentration impurity regions on both sides of the gate electrode 40. On each of the source/drain regions 15, a contact electrode 16 made of Ni silicide is provided.

In the fifteenth embodiment, the gate electrode 40 is made of a metal having an effective work function Φ_{eff} of less than 4.5 eV, such as Ta, HfSiN, or Ti. Therefore, only in the p-type MIS transistor, an element is added to the gate interface to adjust the effective work function Φ_{eff} at the interface to 4.6 eV or more with the help of the effect of an interface electric dipole. It is to be noted that the amount of the additive element to be added to the interface must be 1×10¹³ cm⁻² or more but 1×10¹⁵ cm⁻² or less.

As described above, in the fifteenth embodiment, a metal appropriate to the transistor of one conductivity type is used also for the metal gate electrode of the transistor of the other conductivity type, and the additive element is added only to the transistor of the other conductivity type to adjust the effective work function of the interface to an optimum value for operation of the transistor. By doing so, it is possible to decrease the number of additive elements to only one. In addition, it is also possible to significantly simplify a manufacturing process as compared to a case where an additive element is added to both of the transistors of different conductivity types, because at least one photolithography step and at least one step of adding an additive element can be omitted.

According to the fifteenth embodiment, it is possible to control the effective work function of the gate electrode so that the transistor can have an optimum operating threshold voltage.

### Sixteenth Embodiment

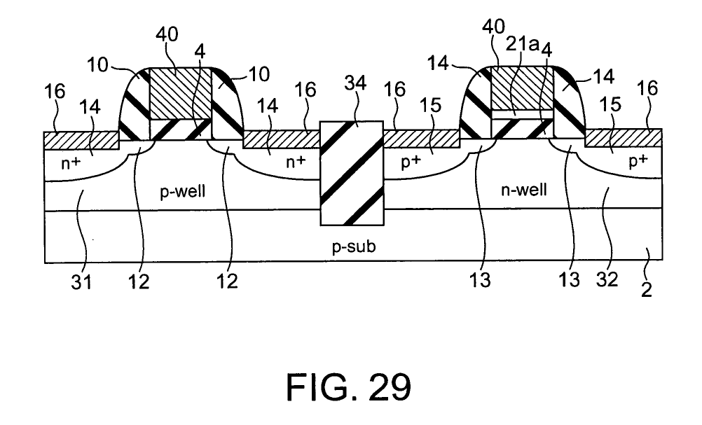

FIG. 29 shows a semiconductor device according to a sixteenth embodiment of the present invention. The semiconductor device according to the sixteenth embodiment has the same structure as the semiconductor device according to the fifteenth embodiment shown in FIG. 28 except that the layer 41 containing carbon (C) and provided on the gate electrode side of an interface between the gate electrode and the gate insulating film of the p-type MIS transistor is replaced with a layer 21a obtained by adding erbium (Er) on the gate insulating film side of the interface at a density of one atomic layer or less so that erbium is bonded to an element constituting the gate electrode 40 through oxygen.

As in the case of the fifteenth embodiment, the gate electrode 40 is made of a metal having an effective work function φ_{eff} of less than 4.5 eV, such as Ta, HfSiN, or Ti. Therefore, only in the p-type MIS transistor, an element is added to the gate interface to adjust the effective work function Φ_{eff} at the interface to 4.6 eV or more with the help of the effect of an interface electric dipole. It is to be noted that the amount of the additive element to be added to the interface must be 1×10¹³ cm⁻² or more but 1×10¹⁵ cm⁻² or less.

As described above, in the sixteenth embodiment, a metal appropriate to the transistor of one conductivity type is used also for the metal gate electrode of the transistor of the other conductivity type, and the additive element is added only to the transistor of the other conductivity type to adjust the effective work function Φ_{eff} of the interface to an optimum value for operation of the transistor. By doing so, it is possible to decrease the number of additive elements to only one. In addition, it is also possible to significantly simplify a manufacturing process as compared to a case where an additive element is added to both of the transistors of different conductivity types, because at least one photolithography step and at least one step of adding an additive element can be omitted.

According to the sixteenth embodiment, it is possible to control the effective work function of the gate electrode so that the transistor can have an optimum operating threshold voltage.

### Seventeenth Embodiment

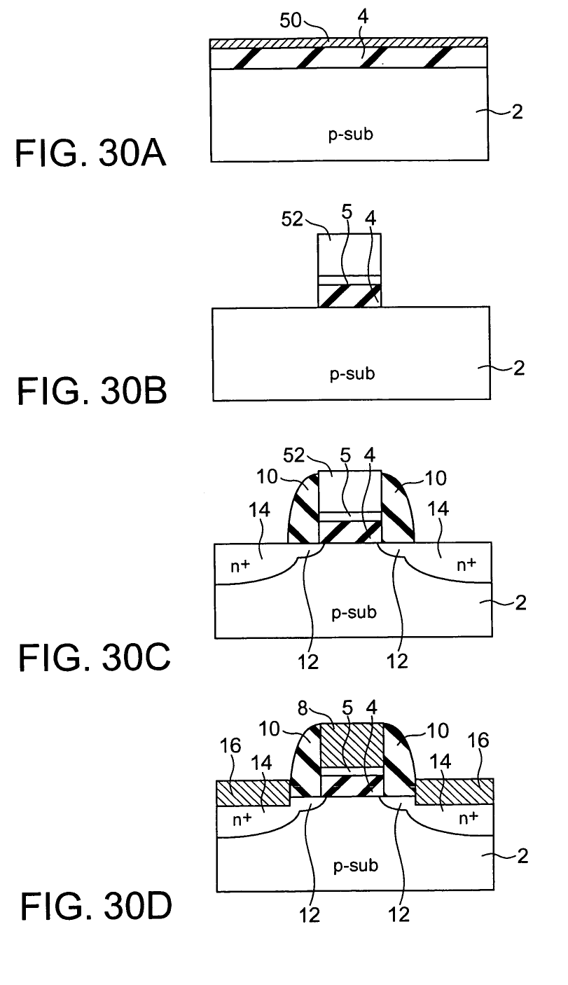

Hereinbelow, a method for manufacturing a semiconductor device according to a seventeenth embodiment of the present invention will be described with reference to FIGS. 30A to 30D. The manufacturing method according to the seventeenth embodiment is a method for manufacturing the semiconductor device according to the first embodiment shown in FIG. 1, and comprises the steps described below.

First, a thermally-oxidized silicon film 4 is formed on the surface of a p-type silicon substrate 2. Then, as shown in FIG. 30A, a layer 50 is formed by adsorbing phosphorus (P) at a areal density of 1×10¹³ cm⁻² or more but one atomic layer or less onto the surface of the thermally-oxidized silicon film 4 provided in an n-type MIS transistor region by the use of a plasma gas of PO(OCH₃)₃. After the completion of adsorption of phosphorus (P), heat treatment is preferably carried out at about 300° C. to 1,000° C. to promote bonding between oxygen and phosphorus. Optimum conditions for heat treatment can be appropriately determined according to adsorption conditions of phosphorus (P). As described above, PO(OCH₃)₃ is used as a material for forming the layer 50 containing phosphorus (P), but the material of the layer 50 may alternatively be PO(OC₂H₅)₃, PO(O-i-C₃H₇)₃, PO(O-n-C₃H₇)₃, PO(O-i-C₄H₉)₃, PO(O-n-C₄H₉)₃, PO(O-sec-C₄H₉)₃, P(OCH₃)₃ or P(OC₂H₅)₃.

Next, polycrystalline silicon is deposited by CVD (Chemical Vapor Deposition) onto the layer 50 so as to have a thickness of 50 nm. Then, the thermally-oxidized silicon film 4 and the layer 50 are patterned by using lithography and anisotropic etching in combination to form a polysilicon film 52 and a gate insulating film 4 formed from the thermally-oxidized silicon film (see FIG. 30B).

Next, ion implantation of arsenic (As) is carried out to form extension layers 12. Then, a gate side wall 10 is formed by using an insulating material (e.g., silicon nitride) onto the side faces of the polysilicon film 52. Thereafter, ion implantation of arsenic (As) is carried out to form source/drain regions 14, and then a side wall for insulating the gate electrode and the source/drain regions is formed and processed (see FIG. 30C).

Next, a Ni film is formed by sputtering so as to have a thickness capable of full silicidation of the polysilicon film 52, and then heat treatment is carried out at about 500° C. to fully silicide the polysilicon film 52. At the same time, a Ni silicide layer is formed also on the source/drain regions 14 to provide a contact electrode 16 for connecting the transistor to an upper wiring (see FIG. 30D). In this way, an n-type MIS transistor according to the first embodiment is obtained.

In the seventeenth embodiment, since Ni silicide is used as the gate electrode, the gate electrode cannot withstand heat treatment for activation of the impurity of the source/drain regions. Therefore, the gate electrode is fully silicided concurrently with the formation of the contact electrode 16 on the source/drain regions 14. By doing so, it is possible to achieve a gate structure with a metal gate electrode. In a case where a metal material or a metal compound material capable of withstanding heat treatment for activation of an impurity is used for the gate electrode, the film of the metal material or metal compound material is deposited onto the insulating film 4 by CVD or PVD (Physical Vapor Deposition) instead of the polycrystalline silicon film shown in FIG. 30B. Further, in a case where a nonmetallic element other than phosphorus (P) is added to an interface between the gate electrode and the gate insulating film, a material containing such a nonmetallic element is used for CVD.

The semiconductor device according to the third embodiment shown in FIG. 11 can also be manufactured by a method similar to the manufacturing method according to the seventeenth embodiment. In the case of the manufacture of the semiconductor device according to the third embodiment, any of the metal elements shown in FIG. 12 is added instead of the nonmetallic element so as to be adsorbed onto the silicon oxide film 4. For example, in a case where erbium (Er) is intended to be adsorbed to the silicon oxide film 4, plasma of Er(O—I—C₃H₇)₃ is used as a material. Other steps are the same as those of the manufacturing method according to the seventeenth embodiment shown in FIGS. 30A to 30D.

By carrying out an additional step after the step of adding a nonmetallic, alkali metal, or rare-earth metal element in the manufacturing method described above, that is, by adding oxygen at a density of one atomic layer so that oxygen is adsorbed onto the surface of the silicon oxide film 4 on which the additive element has been adsorbed, it is possible to manufacture the semiconductor device according to the second modification of the second embodiment shown in FIG. 10 or the semiconductor device according to the second modification of the fourth embodiment shown in FIG. 15. The additional step can be carried out by exposing the substrate to oxygen plasma for a short period of time under the conditions that conspicuous thickening of the gate oxide film does not occur. After the completion of the additional step, by forming a gate electrode in the same manner as the manufacturing method according to the seventeenth embodiment, it is possible to obtain a semiconductor device according to the second modification of the second embodiment shown in FIG. 10 or a semiconductor device according to the second modification of the fourth embodiment shown in FIG. 15.

### Eighteenth Embodiment

Hereinbelow, a method for manufacturing a semiconductor device according to an eighteenth embodiment of the present invention will be described with reference to FIGS. 31A to 31C. The manufacturing method according to the eighteenth embodiment is a method for manufacturing the semiconductor device according to the first embodiment shown in FIG. 1, and comprises the steps described below.

First, a thermally-oxidized silicon film 4 is formed on the surface of a p-type silicon substrate 2. Then, polycrystalline silicon doped with a high-concentration of phosphorus (P) is deposited by CVD onto the thermally-oxidized silicon film 4 so as to have a thickness of 50 nm. The thermally-oxidized silicon film 4 and the polycrystalline silicon film are patterned by using lithography and anisotropic etching in combination to form a polycrystalline silicon film 54 and a gate insulating film 4 formed from the thermally-oxidized silicon film (see FIG. 31A).

Next, ion implantation of arsenic is carried out to form extension layers 12. Then, a gate side wall 10 is formed by using an insulating material (e.g., silicon nitride) onto the side faces of the polycrystalline silicon film 54. Thereafter, ion implantation of arsenic is carried out to form source/drain regions 14 (see FIG. 31B).

Next, a Ni film is formed by sputtering so as to have a thickness capable of full silicidation of the polycrystalline silicon film 54, and then heat treatment is carried out at about 400° C. to fully silicide the polycrystalline silicon film 54. As a result, a gate electrode 8 is formed. At this time, phosphorus (P) homogeneously doped in the polycrystalline silicon film is segregated at an interface between the gate electrode 8 and the gate insulating film 4 due to snow-plow effect associated with silicidation, and is then bonded to oxygen, contained in the gate insulating film 4, at the interface. The P—O bond modulates an interface electric dipole. The amount of phosphorus (P) segregated at the interface can be freely controlled by changing the concentration of phosphorus previously added to the polycrystalline silicon. In a case where an electrode structure is formed by this method, Ni silicide of the second or deeper atomic layers from the interface contains phosphorus at a concentration of about 10 atomic % or less. However, the concentration of phosphorus is so small that the bulk value of the work function of Ni suicide is not changed. During the silicidation of the gate electrode, Ni suicide is formed also on the source/drain regions 14 to provide a contact electrode 16 for connecting the transistor to an upper wiring. In this way, an n-type MIS transistor according to the first embodiment is obtained (see FIG. 31C).

In a case where an additive element other than phosphorus is added to the interface as in the case of the first embodiment, a polycrystalline silicon film containing no impurity is formed on the gate insulating film by CVD, and then ions of any of the nonmetallic elements shown in FIG. 5 are implanted into the polycrystalline silicon. Thereafter, as in the case of phosphorus, the additive element is preferentially inserted into the interface with the gate insulating film with the help of impurity segregation effect associated with silicidation. However, in a case where the additive element has a relatively small atomic radius, the additive element passes through the interface with the gate insulating film so that a large amount of the impurity is inserted into the insulating film side of an interface between the gate electrode and the gate insulating film. In this case, a semiconductor device having a structure according to the second embodiment is obtained. Therefore, in order to obtain a structure according to the first embodiment, it is necessary to use an additive element having a relatively large atomic radius to prevent the additive element from penetrating into the gate insulating film. In a case where a silicon oxide film is used as the gate insulating film, the additive element must have an atomic radius of 0.9 Å or more. When an additive element having an atomic radius of 0.9 Å or less is used, a structure according to the second embodiment is obtained. For example, in a case where boron (B) is used as an additive element, boron (B) is segregated on the silicon oxide film side of the interface so that a structure according to the second embodiment is formed.

Also in a case where germanide is used as a material for the gate electrode, an additive element can be preferentially inserted into the interface with the help of snow-plow effect associated with solid-phase reaction between a metal and Ge.

The semiconductor device according to the third embodiment shown in FIG. 11 can also be manufactured by a method similar to the manufacturing method according to the eighteenth embodiment. In the case of manufacture of the semiconductor device according to the third embodiment, ions of any of the metal elements shown in FIG. 12 instead of the nonmetallic element are implanted into polycrystalline silicon. For example, in a case where erbium (Er) is used as an additive element, ions of erbium are implanted into polycrystalline silicon at an accelerating voltage of about 50 keV. Other steps are the same as those of the manufacturing method according to the eighteenth embodiment shown in FIGS. 31A to 31C. Since the atomic radius of each of the additive elements shown in FIG. 12 is much larger than that of silicon or oxygen, the additive element is segregated in the first atomic layer provided on the gate electrode side of the interface without penetrating into the gate insulating film. Therefore, it is possible to easily obtain a structure according to the third embodiment shown in FIG. 11.

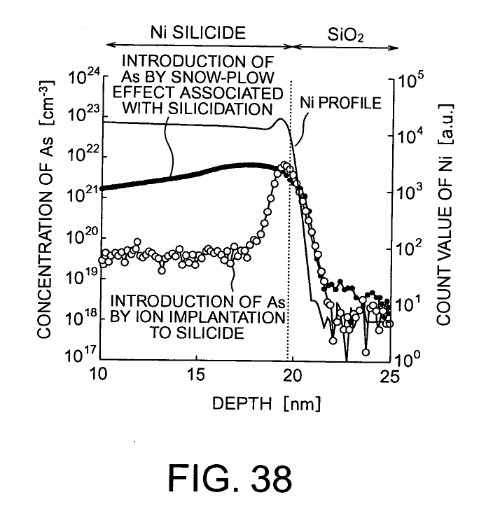

Although addition of an additive element to the interface with the help of snow-plow effect associated with silicidation has been described above, an additive element may also be added by ion implantation to be carried out after the formation of a silicide gate electrode. In this case, heat treatment is carried out at about 300° C. to 500° C. after ion implantation to thermally diffuse an impurity at an interface between the electrode and the gate insulating film. FIG. 38 is a graph which shows As depth distribution in the vicinity of the interface in a case where As is inserted into the interface by ion implantation. The analysis of As depth distribution is carried out in the following manner. The Si substrate of the MOS structure is removed by wet treatment, and then SIMS (Secondary Ion Mass Spectroscopy) analysis is carried out at a low accelerating voltage of about 350 eV from the gate insulating film side. Usually, SIMS analysis is carried out from the electrode surface side, but there are problems such as knocking of an element constituting the electrode and roughness of the surface analyzed by ion irradiation. However, by carrying out SIMS analysis from the gate insulating film side, it is possible to suppress such problems, thereby improving depth resolution in the vicinity of the interface. Therefore, it is possible to precisely define the interface. It is to be noted that an interface between silicide and SiO₂ is defined by a method usually used in determining the interface in SIMS analysis. That is, an interface between silicide and SiO₂ is determined based on a depth at which the count value of the main component of the electrode (in this embodiment, Ni) is half that in the electrode.

As in the case of XPS analysis, FIG. 38 also indicates that As is mainly distributed in the Ni electrode. Further, in a case where As is inserted into an interface between silicide and SiO₂ by carrying out ion implantation after the formation of silicide, the As profile at the interface is steeper as compared to a case where As is inserted into the interface with the help of snow-plow effect associated with silicidation. This indicates that the impurity has been more effectively inserted into the interface. The reason for this is as follows. In a case where As is inserted after the formation of silicide, As is diffused along the grain boundary of silicide and an interface between silicide and the gate insulating film, and as a result As is segregated at the interface. The speed of diffusion of an element along the interface and the grain boundary is one or more orders of magnitude faster than the speed of diffusion of the element in the bulk, and therefore it is possible to effectively insert the impurity into the interface even when the temperature of heat treatment is relatively low.

In the eighteenth embodiment, since Ni silicide is used as the gate electrode, the gate electrode cannot withstand heat treatment for activation of the impurity of the source/drain regions 14. Therefore, polycrystalline silicon is fully silicided concurrently with the formation of the contact electrode 16 on the source/drain regions 14 to achieve a gate structure with a metal gate electrode. In a case where a metal material or a metal compound material capable of withstanding heat treatment for activation of an impurity is used for the gate electrode, the film of the metal material or metal compound material instead of the polycrystalline silicon film shown in FIG. 31A is formed on the insulating film by CVD or PVD. Thereafter, ions of an element to be added to the interface are implanted into the metal electrode, and are then diffused to the gate electrode interface by carrying out heat treatment at 400° C. to 1,000° C. Also in this case, the concentration of the impurity contained in the electrode is made 10 atomic % or less to keep the vacuum work function of the electrode constant.

### Nineteenth Embodiment

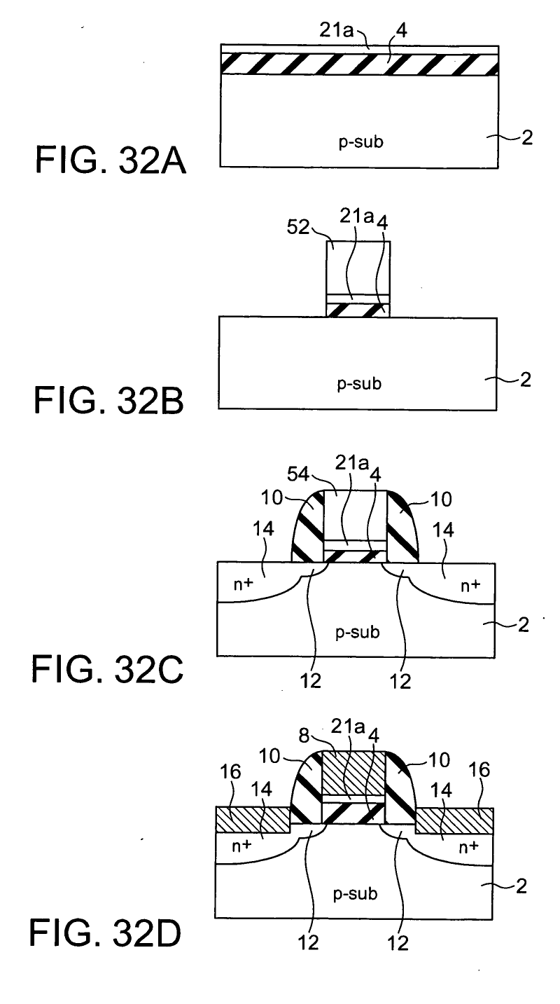

Hereinbelow, a method for manufacturing a semiconductor device according to the nineteenth embodiment of the present invention will be described with reference to FIGS. 32A to 32D. The manufacturing method according to the nineteenth embodiment is a method for manufacturing the semiconductor device according to the fourth embodiment shown in FIG. 13, and comprises the steps described below.

First, as shown in FIG. 32A, a thermally-oxidized silicon film 4 is formed on the surface of a p-type silicon substrate 2. Thereafter, one molecular layer of Er₂O₃ is adsorbed onto the surface of the thermally-oxidized silicon film 4 by spin coating using Er-03 or SYM-ER01 as a material, and is then baked by heat treatment to form a layer 21a made of Er₂O₃.

Next, as shown in FIG. 32B, a polycrystalline silicon film 54 is deposited by CVD onto the layer 21a so as to have a thickness of 50 nm. Then, the polycrystalline silicon film 54, the layer 21a, and the thermally-oxidized silicon film 4 are patterned by using lithography and anisotropic etching in combination.

Next, ion implantation of arsenic is carried out to form extension layers 12. Then, a gate side wall 10 is formed by using an insulating material (e.g., silicon nitride) onto the side faces of the polycrystalline silicon film 54. Thereafter, ion implantation of arsenic is carried out to form source/drain regions 14 (see FIG. 32C).

Next, a nickel (Ni) film is formed by sputtering so as to have a thickness capable of full silicidation of the polycrystalline silicon film 54, and then heat treatment is carried out at about 400° C. to fully silicide the polycrystalline silicon film 54. As a result, a gate electrode 8 is formed. During the silicidation of the polycrystalline silicon film, Ni silicide is formed also on the source/drain regions 14 to provide a contact electrode 16 for connecting the transistor to an upper wiring. In this way, an n-type MIS transistor according to the fourth embodiment shown in FIG. 13 is obtained (see FIG. 32D).

By using a manufacturing method basically the same as any one of the manufacturing methods according to the seventeenth embodiment to the nineteenth embodiment and by using the manufacturing methods according to the seventeenth embodiment to the nineteenth embodiment in combination of two or more of them, it is also possible to easily manufacture the semiconductor devices according to the above-described embodiments other than the first and fourth embodiments by only changing the additive element, the gate electrode material, and the insulating film material.

### Twentieth Embodiment

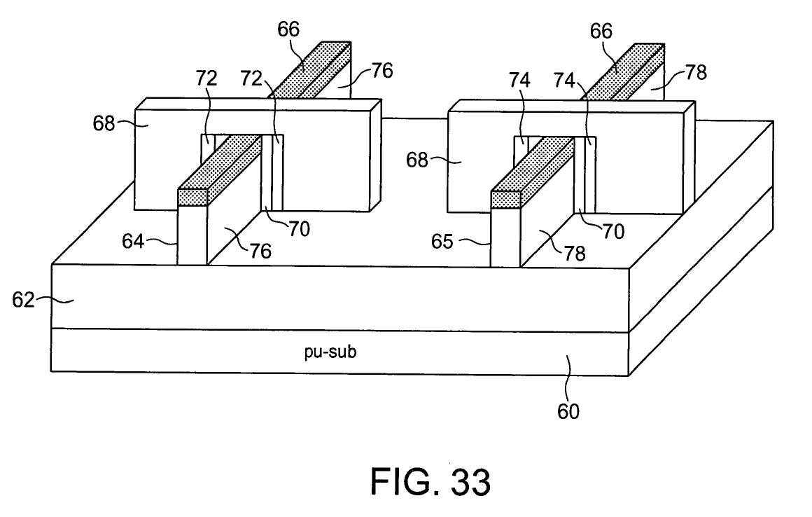

FIG. 33 is a perspective view which shows a semiconductor device according to a twentieth embodiment of the present invention.

In the semiconductor device according to the twentieth embodiment, a buried oxide film 62 is provided on a p-type silicon substrate 60. The buried oxide film 62 is formed by depositing oxide silicon onto the p-type silicon substrate 60. On the buried oxide film 62, Fin structures each including a channel region and source/drain regions of a transistor are provided. The Fin structure of an n-type MIS transistor has a laminated structure of a p-type silicon layer 64 and a SiN layer 66. On the other hand, the Fin structure of a p-type MIS transistor has a laminated structure of an n-type silicon layer 65 and a SiN layer 66. Alternatively, the Fin structure may have either a single layer structure of silicon or a laminated structure of a silicon layer and an insulating layer made of a material other than SiN.

A gate electrode 68 made of Ni silicide is provided so as to intersect with the Fin structure. At the contact interface between the gate electrode 68 and the silicon layer 64 constituting the Fin structure, a gate insulating film 70 formed from a silicon oxide film is provided. Also at the contact interface between the gate electrode 68 and the silicon layer 65 constituting the Fin structure, a gate insulting film 70 formed from a silicon oxide film is provided. Each of the MIS transistors having such a structure described above is a so-called “double-gate MIS transistor” which has channel regions in both side faces of the silicon layer 64 or 65 constituting the Fin structure. In a case where a silicon single layer is used as a Fin structure, the upper face of the Fin structure also provides a channel region, and therefore it is possible to obtain a tri-gate MIS transistor.

At an interface between the gate electrode 68 of the n-type MIS transistor and the silicon layer 64 constituting the Fin structure, a layer 72 containing nitrogen (N) on the Ni silicide electrode side at a areal density of 1×10¹³ cm⁻² or more but one atomic layer or less is provided. On the other hand, at an interface between the gate electrode 68 of the p-type MIS transistor and the silicon layer 65 constituting the Fin structure, a layer 74 containing erbium (Er) on the Ni silicide electrode side at a areal density of 1×10¹³ cm⁻² or more but one atomic layer or less is provided.

In the p-type silicon layer 64, source/drain regions 76 are provided as n-type high-concentration impurity regions so as to sandwich the channel regions. In the n-type silicon layer 65, source/drain regions 78 are provided as p-type high-concentration impurity regions so as to sandwich the channel regions.

In such a three-dimensional device element according to this embodiment, it is very difficult to achieve the uniformity in impurity concentration in a height direction. Therefore, as in the case of the semiconductor device according to the fifth embodiment shown in FIG. 16, a Schottky source/drain structure may alternatively be employed.

The semiconductor device according to the twentieth embodiment is an example in which the gate electrode interface structure shown in FIG. 24 is applied to a Fin-type transistor. That is, each of the gate electrode interface structures according to the first to nineteenth embodiments can be applied not only to a planar-type transistor but also to a three-dimensional transistor. In the case of a three-dimensional transistor, it is significantly difficult to form a gate electrode interface structure as compared to the case of a two-dimensional planar transistor. Further, the use of different metal materials for gate electrodes of different conductivity types not only leads to an increase in costs but also makes it very difficult to manufacture gate electrodes from a technical viewpoint. However, according to this embodiment, it is possible for the transistor to have an optimum operating threshold voltage only by adding an element to the interface. Therefore, such an effect obtained by this embodiment is significantly large. Further, the semiconductor device according to the twentieth embodiment can be manufactured by a method obtained by optimizing the manufacturing method of a planar semiconductor device.

In the twentieth embodiment, a double-gate MIS transistor having a Fin structure is used, but a planar-type double-gate CMIS transistor, a vertical double-gate CMIS transistor, or other three-dimensional device elements may alternatively be used.

In each of the first to twentieth embodiments, silicon (Si) is used for the channel region, but SiGe, germanium (Ge) or a strained-silicon (Si) having a higher mobility than that of silicon (Si) or a silicon layer having a SOI (Silicon On Insulator) structure may alternatively be used.

As has been described above, according to each of the embodiments of the present invention, it is possible to control the effective work function of the gate electrode so that the transistor can have an optimum operating threshold voltage.

It is to be noted that various modifications may be made to the present invention without departing from the spirit of the invention.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A semiconductor device comprising:
a semiconductor substrate;
a gate insulating film provided on the semiconductor substrate;
a gate electrode provided on the gate insulating film;
source/drain regions provided in the semiconductor substrate on both sides of the gate electrode; and
a layer which is provided at an interface between the gate electrode and the gate insulating film, and contains an element having an electronegativity different from those of elements constituting the gate electrode and the gate insulating film.

2. The semiconductor device according to claim 1, wherein the element having an electronegativity different from those of elements constituting the gate electrode and the gate insulating film has a Pauling's electronegativity larger than 1.9.

3. The semiconductor device according to claim 1, wherein the element having an electronegativity different from those of elements constituting the gate electrode and the gate insulating film has a Pauling's electronegativity smaller than 1.9.

4. The semiconductor device according to claim 1, wherein the element having an electronegativity different from those of elements constituting the gate electrode and the gate insulating film has a Pauling's electronegativity larger than that of an element constituting the gate electrode.

5. The semiconductor device according to claim 1, wherein the element having an electronegativity different from those of elements constituting the gate electrode and the gate insulating film has a Pauling's electronegativity smaller than that of an element constituting the gate electrode.

6. The semiconductor device according to claim 1, wherein the element having an electronegativity different from those of elements constituting the gate electrode and the gate insulating film has a Pauling's electronegativity larger than that of an element constituting the gate insulating film.

7. The semiconductor device according to claim 1, wherein the element having an electronegativity different from those of elements constituting the gate electrode and the gate insulating film has a Pauling's electronegativity smaller than that of an element constituting the gate insulating film.

8. The semiconductor device according to claim 1, wherein the element having an electronegativity different from those of elements constituting the gate electrode and the gate insulating film is at least one element selected from the group consisting of B, Sb, P, As, C, N, Cl, F, Sn, Pb, Bi, Ge, and Xe.

9. The semiconductor device according to claim 1, wherein the element having an electronegativity different from those of elements constituting the gate electrode and the gate insulating film is at least one element selected from the group consisting of In, Al, Y, Dy, Er, Cs, Sr, Ba, and Rb.

10. The semiconductor device according to claim 1, wherein the maximum areal density of the element having an electronegativity different from those of elements constituting the gate electrode and the gate insulating film is 1×10¹³ cm⁻² or more but 1×10¹⁵ cm⁻² or less at an interface between the gate electrode and the gate insulating film.

11. A semiconductor device comprising:
a semiconductor substrate;
a gate insulating film provided on the semiconductor substrate;
a gate electrode provided on the gate insulating film;
source/drain regions provided in the semiconductor substrate on both sides of the gate electrode; and
a layer which is provided as at least a first atomic layer on the gate electrode side of an interface between the gate electrode and the gate insulating film, and includes an element having an electronegativity different from those of elements constituting the gate electrode and the gate insulating film.

12. The semiconductor device according to claim 11, wherein the element having an electronegativity different from those of elements constituting the gate electrode and the gate insulating film is bonded to oxygen or nitrogen contained in the gate insulating film.

13. The semiconductor device according to claim 11, wherein the element having an electronegativity different from those of elements constituting the gate electrode and the gate insulating film has a Pauling's electronegativity larger than 1.9.

14. The semiconductor device according to claim 11, wherein the element having an electronegativity different from those of elements constituting the gate electrode and the gate insulating film has a Pauling's electronegativity smaller than 1.9.

15. The semiconductor device according to claim 11, wherein the element having an electronegativity different from those of elements constituting the gate electrode and the gate insulating film has a Pauling's electronegativity larger than that of an element constituting the gate electrode.

16. The semiconductor device according to claim 11, wherein the element having an electronegativity different from those of elements constituting the gate electrode and the gate insulating film has a Pauling's electronegativity smaller than that of an element constituting the gate electrode.

17. The semiconductor device according to claim 11, wherein the element having an electronegativity different from those of elements constituting the gate electrode and the gate insulating film has a Pauling's electronegativity larger than that of an element constituting the gate insulating film.

18. The semiconductor device according to claim 11, wherein the element having an electronegativity different from those of elements constituting the gate electrode and the gate insulating film has a Pauling's electronegativity smaller than that of an element constituting the gate insulating film.

19. The semiconductor device according to claim 11, wherein the element having an electronegativity different from those of elements constituting the gate electrode and the gate insulating film is at least one element selected from the group consisting of B, Sb, P, As, C, N, Cl, F, Sn, Pb, Bi, Ge, and Xe.

20. The semiconductor device according to claim 11, wherein the element having an electronegativity different from those of elements constituting the gate electrode and the gate insulating film is at least one element selected from the group consisting of In, Al, Y, Dy, Er, Cs, Sr, Ba, and Rb.

21. The semiconductor device according to claim 11, wherein the maximum areal density of the element having an electronegativity different from those of elements constituting the gate electrode and the gate insulating film is 1×10¹³ cm⁻² or more but 1×10¹⁵ cm⁻² or less at an interface between the gate electrode and the gate insulating film.

22. A semiconductor device comprising:
a semiconductor substrate;
a gate insulating film provided on the semiconductor substrate;
a gate electrode provided on the gate insulating film;
source/drain regions provided in the semiconductor substrate on both sides of the gate electrode; and
a layer which is provided as a second or deeper atomic layer on the gate insulating film side of an interface between the gate electrode and the gate insulating film, and includes an element having an electronegativity different from those of elements constituting the gate electrode and the gate insulating film, the element being bonded to an element which the gate electrode include through an oxygen atom.

23. The semiconductor device according to claim 22, wherein the element having an electronegativity different from those of elements constituting the gate electrode and the gate insulating film is bonded to oxygen or nitrogen contained in the gate insulating film.

24. The semiconductor device according to claim 22, wherein the element having an electronegativity different from those of elements constituting the gate electrode and the gate insulating film has a Pauling's electronegativity larger than 1.9.

25. The semiconductor device according to claim 22, wherein the element having an electronegativity different from those of elements constituting the gate electrode and the gate insulating film has a Pauling's electronegativity smaller than 1.9.

26. The semiconductor device according to claim 22, wherein the element having an electronegativity different from those of elements constituting the gate electrode and the gate insulating film has a Pauling's electronegativity larger than that of an element constituting the gate electrode.

27. The semiconductor device according to claim 22, wherein the element having an electronegativity different from those of elements constituting the gate electrode and the gate insulating film has a Pauling's electronegativity smaller than that of an element constituting the gate electrode.

28. The semiconductor device according to claim 22, wherein the element having an electronegativity different from those of elements constituting the gate electrode and the gate insulating film has a Pauling's electronegativity larger than that of an element constituting the gate insulating film.

29. The semiconductor device according to claim 22, wherein the element having an electronegativity different from those of elements constituting the gate electrode and the gate insulating film has a Pauling's electronegativity smaller than that of an element constituting the gate insulating film.

30. The semiconductor device according to claim 22, wherein the element having an electronegativity different from those of elements constituting the gate electrode and the gate insulating film is at least one element selected from the group consisting of B, Sb, P, As, C, N, Cl, F, Sn, Pb, Bi, Ge, and Xe.

31. The semiconductor device according to claim 22, wherein the element having an electronegativity different from those of elements constituting the gate electrode and the gate insulating film is at least one element selected from the group consisting of In, Al, Y, Dy, Er, Cs, Sr, Ba, and Rb.

32. The semiconductor device according to claim 22, wherein the maximum areal density of the element having an electronegativity different from those of elements constituting the gate electrode and the gate insulating film is 1×10¹³ cm⁻² or more but 1×10¹⁵ cm⁻² or less at an interface between the gate electrode and the gate insulating film.

33. A semiconductor device comprising:
a semiconductor substrate;
a gate insulating film provided on the semiconductor substrate;
a gate electrode provided on the gate insulating film;
source/drain regions provided in the semiconductor substrate on both sides of the gate electrode;
a first layer which is provided as at least a first atomic layer on the gate electrode side of an interface between the gate electrode and the gate insulating film, and includes a first element having an electronegativity different from those of elements constituting the gate electrode and the gate insulating film; and
a second layer which is provided as a second or deeper atomic layer on the gate insulating film side of an interface between the gate electrode and the gate insulating film, and includes a second element having an electronegativity different from those of elements constituting the gate electrode and the gate insulating film, the second element being bonded to an element which the gate electrode include through an oxygen atom.

34. The semiconductor device according to claim 33, wherein the maximum areal density of each of the first and second elements is 1×10¹³ cm⁻² or more but 1×10¹⁵ cm⁻² or less at an interface between the gate electrode and the gate insulating film.

35. A semiconductor device comprising:
a convex semiconductor layer provided on an insulating layer formed on a substrate;
a gate electrode provided to cross and straddle the semiconductor layer;
a gate insulating film provided at the intersection region between the semiconductor layer and the gate electrode;
source/drain regions provided in the semiconductor layer on both sides of the gate electrode; and
a layer provided at an interface between the gate electrode and the gate insulating film and containing an element having an electronegativity different from those of elements constituting the gate electrode and the gate insulating film.
